(19) United States
(12) Patent Application Publication
(10) Pub. No.: US 2025/0258208 A1
(43) Pub. Date: Aug. 14, 2025

(54) REAL-TIME ENERGY TRACKING METHOD AND SYSTEM

(71) Applicant: Empati Limited, Greater London (GB)

(72) Inventors: Sarvapali Ramchurn, Hampshire (GB); Stewart Dodd, Greater London (GB); Oliver Nunn, Greater London (GB); Elliot Salisbury, Squamish (CA); Trung Dong Huynh, Hampshire (GB)

(21) Appl. No.: 18/858,241

(22) PCT Filed: Apr. 18, 2023
(86) PCT No.: PCT/GB2023/051020

§ 371 Date: Oct. 18, 2024

(30) Foreign Application Priority Data
Apr. 20, 2022 (GB) 2205770.7

(51) Int. Cl. G01R 21/133; G06Q 50/06

(52) U.S. Cl. CPC G01R 21/133; G06Q 50/06

(57) ABSTRACT

A method of real-time energy-tracking including: measuring the energy produced by an energy generator and the energy consumed by an energy consumer; collecting generated energy measurements and consumed energy measurements over a specified time period; receiving data packets containing these measurements along with associated temporal metadata, wherein by aligning the generated energy measurements with the consumed energy measurements based on this temporal data, the method creates matched sets of measurements, wherein for each matched set, it assesses the energy balance by comparing the generated energy to the corresponding consumed energy, thereby identifying any real-time energy deficit or excess.

### TECHNICAL FIELD

The invention relates to tracking energy in an energy distribution network or grid, and particularly to measuring and tracking energy generation and consumption in real-time.

### BACKGROUND OF INVENTION

In energy networks and electrical grids, energy is usually generated at a plurality of energy generation sites, and provided to a plurality of consumers. The energy generation sites may be of different types, related to different energy sources and managed by different operators. Similarly, consumers may be different individuals, companies or the like and consume variable amounts of energy.

The energy generators and consumers are connected by a network of transmission and distribution lines, substations and energy storage mechanisms.

The consumption of energy by consumers is not constant and as such, demand for energy is highly variable depending on a plurality of factors such as time of day, weather, consumer habits and consumer location.

The energy network or grid increasingly includes energy from renewable or ‘green’ energy sources, but still includes energy generated from conventional sources such as coal and natural gas. At times of peak demand, a consumer can expect to be provided energy that originates from any number of sources, including both green and conventional energy sources.

At present, energy in the network or grid is not tracked rigorously. Total energy generated and consumed may be recorded in discrete hourly or half-hourly blocks. However, a problem exists in using such discrete blocks, as the energy generated in the block may not correlate to the energy that appears to be consumed in the block. For example, an energy consumer may consume 4 kWh of energy within the first five minutes of a half-hourly block, whilst an energy generator may generate 10 kWh of energy in the last ten minutes of the half-hourly block. However, since the blocks are discrete, and do not provide more granular detail, the block only indicates that 10 kWh of energy is generated whilst 4 kWh is consumed. It may thus appear, from this half-hourly block of data, that the generator provided or was capable of providing the 4 kWh of demand from the energy consumer and was further able to deliver a 6 kWh surplus of energy for other consumers. This is incorrect, since in reality the 10 kWh of energy was only generated in the last ten minutes of the half-hourly block, after the energy consumer demand of 4 kW in the first five minutes. Therefore, in reality, the energy consumer was provided energy from a different source than the energy generator in the first five minutes of the block.

Using hourly or half-hourly blocks is therefore inaccurate and unreliable, and data relating to actual energy generation and consumption is lost. Rather, these blocks only provide an estimation or prediction of which sources of energy are attributed to consumed energy.

A further disadvantage relating to the use of such discrete blocks is that it is impossible to accurately match particular energy generators to energy consumers.

Furthermore, such energy blocks may not include energy generated at some energy generators due to the fact that many energy generators do not provide information or instead only produce proprietary data.

It has thus been appreciated that a more accurate and reliable method and system for energy tracking is required.

### SUMMARY OF INVENTION

This Summary is provided to introduce a selection of concepts in a simplified form that are further described below in the Detailed Description. This Summary is not intended to identify key features or essential features of the claimed subject matter, nor is it intended to be used to determine the scope of the claimed subject matter; variants and alternative features which facilitate the working of the invention and/or serve to achieve a substantially similar technical effect should be considered as falling into the scope of the invention disclosed herein.

In a first aspect, the present disclosure provides a computer-implemented method of real-time energy-tracking, the method comprising: measuring, in real-time with an energy generation sensor, energy generated at an energy generator to obtain a plurality of generated energy measurements over a period of time; measuring, in real-time with an energy consumption sensor, energy consumed by an energy consumer to obtain a plurality of consumed energy measurements over the period of time; receiving a plurality of generator data packets, each generator data packet including one of the plurality of generated energy measurements, and associated generator metadata including temporal data corresponding to a time at which the one of the plurality of generated energy measurements was measured; receiving a plurality of consumption data packets, each consumption data packet including one of the plurality of consumed energy measurements, and associated consumer metadata including temporal data corresponding to a time at which the one of the plurality of consumed energy measurements was measured; matching the plurality of generated energy measurements to the plurality of consumed energy measurements according to the temporal data from each of the generator metadata and the consumer metadata to obtain a plurality of sets of matched measurements over the period of time; and for each of the sets of matched measurements over the period of time, determining and outputting a real-time energy deficit or excess by comparing the generated energy measurement to its matched consumed energy measurement.

By measuring and recording generated energy measurements and consumed energy measurements in real-time, at high frequency, measurements are matched in a reliable and accurate manner, and the determination of a real-time energy excess or deficit is possible for a particular instance in time. Matching energy generated to energy consumed in this way ensures that discrepancies or mismatches between energy generated and energy consumed do not exist over the longer period of time.

The set of matched measurements may be considered a linked group of data. The set of matched measurement, may, in some instances, only include generated energy measurements or only consumed energy measurements, if for example, the energy generator is not active during said instance.

Preferably, for each set of matched measurements of the plurality of sets of matched measurements, the method further comprises: retrieving a grid carbon intensity associated with an electrical grid connected to the energy consumer; retrieving an energy generator carbon intensity associated with the energy generator; determining a consumer carbon intensity associated with the set of matched measurements, wherein the consumer carbon intensity is a weighted average of: the grid carbon intensity, weighted according to the real-time energy deficit of the set of matched measurements; and the energy generator carbon intensity, weighted according to the corresponding generated energy measurement of the set of matched measurements; and outputting the consumer carbon intensity.

The consumer carbon intensity may be referred to simply as carbon intensity of carbon intensity of energy consumption, and is a measure of the mass of carbon dioxide per kilowatt hour of energy generated. This measure can be usefully output to track how ‘green’ a consumer's energy consumption is, and to more generally track the carbon intensity of energy generation.

Preferably, the method further comprises accumulating the consumer carbon intensity for each set of matched measurements over the period of time; and averaging the consumer carbon intensity over the period of time to determine an average consumer carbon intensity; and outputting the average consumer carbon intensity.

Thus, the carbon intensity can be averaged over a longer period of time, for example a day, to indicate the average carbon intensity of a consumer's energy consumption. The average is also calculated using a weighting according to the total energy consumed in each set of matched measurements.

Preferably, retrieving the grid carbon intensity comprises: determining the energy consumer associated with the consumed energy measurement; determining an alternative energy supplier associated with the energy consumer; and retrieving an alternative supplier carbon intensity associated with the alternative energy supplier, such that the grid carbon intensity is set as the alternative supplier carbon intensity.

Using the grid carbon intensity allows the method to account for energy generators that are not being directly monitored as well as those that are. The grid carbon intensity may be directly measured, sampled, or obtained from third party information. Using the carbon intensity of an alternative supplier of a consumer provides a highly accurate value for the grid carbon intensity, since, in the case of an energy deficit, the energy consumer will acquire energy from the grid from the alternative supplier.

Preferably, the method further comprises determining, from the consumer carbon intensity of the set of matched measurements, and the consumed energy measurement in the set of matched measurements, a real-time carbon content associated with the energy consumed by the energy consumer in the set of matched measurements; and outputting the real-time carbon content.

The real-time carbon content is a measure of carbon-dioxide emissions in grams, and thus is a measure of the consumer's carbon footprint in terms of energy consumed.

Preferably, the method further comprises comparing the consumer carbon intensity to a first threshold value; and when the consumer carbon intensity matches or exceeds the first threshold value: taking an action to reduce the consumer carbon intensity. Thus, an action can be performed in response to high consumer carbon intensity values, to ensure that the consumer carbon intensity is reduced.

Preferably, the action to reduce consumer carbon intensity includes at least one of: activating an alarm to alert the energy consumer; sending an instruction to activate a further energy generator, or to increase energy generation by the energy generator, to increase energy generated; and informing the energy consumer to reduce energy consumption.

The energy generator and or the further energy generator to be activated may be a green energy generator, associated with a relatively low or zero-value carbon intensity. Thus, increasing energy generation or activating energy generation from said further energy generator and/or the energy generator results in more ‘green’ energy being generated as a proportion of total energy generated. This means that, overall, the carbon intensity of energy generation, and ultimately the consumer carbon intensity associated with an energy consumer's energy consumption, is reduced. Informing the energy consumer to reduce energy consumption may include sending an alert, reminder or the like for display or other notification at a device associated with the consumer. The device may be a personal computing device associated with the consumer, such as a computer, tablet or mobile phone. Alternatively, the device may be part of or incorporated with the energy consumption sensor. The energy consumption sensor may thus include a display, speaker, or the like for providing a notification or information to the consumer. The action taken in the method may be communicated to the consumer device via any appropriate communication channel, such as over the internet, by phone, Wi-Fi, LAN, cellular data or any other communication network.

Preferably, the period of time is a second, a minute, an hour, a week, a month or a year. Thus, the consumer carbon intensity, the energy deficit or excess, and/or the real-time carbon content, which are determined based on sets of matched real-time measurements, may be averaged and accumulated over the longer period of time. Since these averages and/or accumulations depend on real-time measurements, the accuracy and reliability is conserved.

Preferably, the method further includes measuring, in real-time, at a frequency of 1 Hz or higher.

Preferably, there is a plurality of energy generators, such that the method comprises measuring, in real-time with a plurality of energy generation sensors, energy generated at the plurality of energy generators, to obtain a plurality of generated energy measurements for each of the plurality of energy generators over the period of time; receiving a plurality of generator data packets for each of the energy generators, each generator data packet including one of the plurality of generated energy measurements, and associated generator metadata including temporal data corresponding to a time at which one of the plurality of consumed energy measurements was measured; matching the plurality of generated energy measurements from each of the plurality of energy generators to the plurality of consumed energy measurements according to the temporal data from each of the generator metadata and the consumer metadata, to obtain the plurality of sets of matched measurements, wherein each set of matched measurements includes a generated energy measurement from each energy generator; and for each set of matched measurements over the period of time, determining and outputting a real-time energy deficit or excess by comparing the generated energy measurements from each of the plurality of energy generators to their matched consumed energy measurement.

Therefore, the matched set of measurements comprises multiple generated energy measurements corresponding to multiple energy generators. These multiple matched generated energy measurements are matched to each other and may be matched to a consumed energy measurement. Thus, the method can advantageously incorporate measurements and data from a range of sources.

Preferably, the plurality of energy generators includes a plurality of types of energy generators. The energy generators may include green and/or conventional type energy generators. The types of energy generator may be wind, solar, tidal, hydroelectric, nuclear, gas, coal and the like. The plurality of energy generators may include different energy generators of the same type.

Preferably, the method further comprises determining, from the generated energy measurements for each of the energy generators, a real-time proportion of a total energy generated by the plurality of energy generators attributed to each individual and/or type of energy generator; and outputting the real-time proportion of the total energy generated by the plurality of energy generators attributed to each type of energy generator.

The real-time proportion may be a percentage of the total energy generated. Since the proportion is determined from the set of matched measurements, the real-time aspects of the matched set of measurements is conserved in the real-time proportion. The real-time proportion may be averaged over the period of time according to the total energy generated over several sets of matched measurements. The real-time proportion advantageously provides an indication of which of the plurality of energy generators are providing the most and least energy at any instance in time.

Preferably, the method further comprises a plurality of energy consumers, such that the method comprises: measuring, with a plurality of energy consumption sensors, energy consumed by a plurality of energy consumers; receiving a plurality of consumption data packets for each energy consumer, each consumption data packet including one of the plurality of consumed energy measurements, and associated consumer metadata including temporal data corresponding to a time at which the one of the plurality of consumed energy measurements was measured; matching the plurality of generated energy measurements to the plurality of consumed energy measurements from each of the plurality of energy consumers according to the temporal data from each of the generator metadata and the consumer metadata to obtain the plurality of sets of matched measurements over the period of time, wherein each set of matched measurements includes a consumed energy measurement from each energy consumer; and for each of the sets of matched measurements over the period of time, determining and outputting a real-time energy deficit or excess by comparing the generated energy measurement to its matched consumed energy measurements from the plurality of energy consumers.

The method may thus be performed with respect to a plurality of consumers and a plurality of energy generators.

Preferably, determining the consumer carbon intensity for each set of matched measurements comprises: determining an individual consumer carbon intensity for each energy consumer represented in the set of matched measurements by: retrieving an alternative supplier carbon intensity for each energy consumer represented in the set of matched measurements; splitting the real-time energy deficit for the set of matched measurements into a plurality of energy deficit portions based on the consumed energy measurements in the set of matched measurements, each energy deficit portion attributed to a respective energy consumer of the plurality of energy consumers represented in the set of matched measurements; calculating the individual consumer carbon intensity for each energy consumer by taking a weighted average of: the respective alternative supplier carbon intensity for the energy consumer, weighted according to the energy deficit portion attributed to the energy consumer; and the energy generator carbon intensity, weighted according to the corresponding generated energy measurement of the set of matched measurements; and outputting the individual consumer carbon intensity for each energy consumer represented in the set of matched measurements.

Determining an individual consumer carbon intensity for each energy consumer, such that the individual consumer carbon intensity is dependent on the energy consumer, means that the consumer carbon intensity is more accurate and reliable based on the specific circumstances of the energy consumer. In particular, basing the consumer carbon intensity on an alternative supplier carbon intensity, whereby the alternative supplier is associated with the specific energy consumer, rather than using the electrical grid carbon intensity, is more accurate and more closely reflects the true carbon intensity value for energy sourced outside of the one or more energy generators being monitored by the energy generator sensors.

The determination of the individual consumer carbon intensity may take into account more than one energy generator if more than one energy generator is being monitored.

The determination of the individual carbon intensity is determined using an average of all carbon intensities of the energy generators and the carbon intensity of the alternative supplier, whereby the carbon intensity of the alternative supplier is weighted according to a determined energy deficit portion. The energy deficit portion may be proportional, across several energy consumers, to the energy consumed by each energy consumer. Alternatively, the energy deficit portion may be determined by splitting the energy deficit equally amongst the energy consumers, or by splitting the energy deficit according to a priority listing of energy consumers, whereby higher priority consumers are attributed less of the deficit.

Preferably, the generator metadata comprises any one or more aspects including: data indicative of a type of energy generator used; data indicative of an entity associated with the energy generator used; and/or data indicative of an activity or condition associated with the energy generator used; and/or wherein the consumer metadata comprises any one or more aspects including: data indicative of a type of energy consumer; data indicative of an entity associated with the energy consumer; and/or data indicative of an activity or condition associated with the energy consumer.

Preferably, the method further comprises further matching the plurality of generated energy measurements to the plurality of consumed energy measurements according to any one or more aspects of the generator metadata and/or the consumer metadata to obtain a plurality of sets of secondary-matched measurements over the period of time; and outputting the secondary matched measurements.

In this way, secondary sets of matched measurements, or secondary linked groups of data may be formed. Similar processing with respect to the energy mix, carbon intensity and carbon content may be performed with respect to the secondary sets of matched measurements. The matched measurements may be stored in a relational database.

Preferably, outputting comprises storing data in a database in a preconfigured format.

Storing in a preconfigured format allows each and all of the sets of matched measurements to be compared and/or accumulated, and otherwise processed collectively. It also allows third parties, such as energy consumers and operators of energy generators, to access the data stored in the database without having to translate or reconfigure data.

Preferably, outputting further comprises outputting any one or more of: the sets of matched measurements according to the temporal metadata; the consumer metadata; and the generator metadata.

Thus, the set of matched measurements, and/or the secondary set of matched measurements may be stored, displayed or processed based on common metadata.

Preferably, the method further comprises storing, in an directed acyclic graph, at least two of: an indication of the energy generator, indication of the energy consumer, the plurality of sets of matched measurements for the energy generator and the energy consumer, the real-time energy deficit or excess determined for each of the matched measurements over the period of time, and a record of one or more calculations corresponding to the one or more of the determining steps.

The acyclic graph advantageously provides an audit-trail of the sources of data, such as sensors at the energy generators and energy consumers, the manipulation of such data, such as summing, averaging, calculating the deficit/excess, carbon content, energy mix and carbon intensity, and the results provided by these manipulations. This allows for critical analysis by third parties such as the energy consumer and the energy generator operator.

Preferably, the preconfigured format is provenance (PROV), and uses the provenance data model (PROV-DM). The vocabulary of the PROV-DM is adjustable based on the particular implementation of the energy tracking method and the specific application within which it is deployed.

Preferably, the method further comprises storing a hash of the directed acyclic graph in a block-chain or distributed ledger with a cryptographic hash function.

The hash may be of the directed acyclic graph and/or of the sets of matched measurements. The set of matched measurements, or the plurality of sets of matched measurements form a datasets. The hash and the dataset may be used to verify, using any appropriate algorithm, that the dataset is valid and has not been tampered with.

Preferably, the method further comprises measuring, in real-time, energy generated at the energy generator with a first group of sensors, wherein the first group of sensors includes at least two types of sensor arranged in an energy generation chain with the energy generation sensor and/or co-located with the energy generation sensor.

Having multiple sensors at the energy generator to form the first group of sensors advantageously allows for sensor redundancy, such that if one sensor in the first group fails, another may be used to measure energy generated. Having multiple sensors in the first group also allows for faults to be determined. The first group of sensors may include secondary sensors such as weather sensors, temperature sensors, moisture sensors, irradiance sensors and the like. The use of such sensors can be used in combination with energy generator sensors to provide context for the generated energy measurements.

Preferably, the method further comprises verifying the generated energy measurements of the energy generation sensor based on measurements of the first group of sensors.

Preferably, the method further comprises measuring energy generated at a renewable energy generator.

Preferably, the method further comprises, before measuring, synchronising a first clock signal used at the energy generation sensor with a second clock signal used at the energy consumption sensor.

Synchronising the first and second clock signals ensures that the high-frequency real-time measurements can be matched accurately. The clock signals may be synchronised periodically, for example, every second, ten seconds, 1 minute 5 minutes, every 10 minutes, every hour or every day.

According to a second aspect, there is provided one or more energy generation sensors configured to measure, in real-time, energy generated at one or more energy generators; one or more energy consumption sensors configured to measure, in real-time, energy consumed by one or more energy consumers; and a processor communicatively coupled with the one or more energy generation sensors and the one or more energy consumption sensors, the processor configured to execute the method according to the first aspect above.

According to a third aspect, there is provided a computer-program for performing real-time energy tracking, which, when executed by a processor, is configured to cause the processor to: receive a plurality of generator data packets, each generator data packet including one of a plurality of real-time generated energy measurements, and associated generator metadata including temporal data corresponding to a time at which the one of the plurality of real-time generated energy measurements was measured; receive a plurality of consumption data packets, each consumption data packet including one of a plurality of real-time consumed energy measurements, and associated consumer metadata including temporal data corresponding to a time at which the one of the plurality of real-time consumed energy measurements was measured; match the plurality of generated energy measurements to the plurality of consumed energy measurements according to the temporal data from each of the generator metadata and the consumer metadata to obtain a plurality of sets of matched measurements over the period of time; and for each of the sets of matched measurements over the period of time, determine and output a real-time energy deficit or excess by comparing the generated energy measurement to its matched consumed energy measurement.

According to an additional aspect, there is provided an additional method of energy tracking, the method comprising: measuring, in real-time with an energy generation sensor, energy generated at an energy generator to obtain a plurality of generated energy measurements over a period of time; measuring, in real-time with an energy consumption sensor, energy consumed by an energy consumer to obtain a plurality of consumed energy measurements over the period of time; receiving a plurality of generator data packets, each generator data packet including one of the plurality of generated energy measurements, and associated generator metadata including temporal data corresponding to a time at which the one of the plurality of generated energy measurements was measured; receiving a plurality of consumption data packets, each consumption data packet including one of the plurality of consumed energy measurements, and associated consumer metadata including temporal data corresponding to a time at which the one of the plurality of consumed energy measurements was measured; matching the plurality of generated energy measurements to the plurality of consumed energy measurements according to the temporal data from each of the generator metadata and the consumer metadata to obtain a plurality of sets of matched measurements over the period of time; and for each of the sets of matched measurements over the period of time, determining and outputting the carbon intensity of the energy generated, based on a carbon intensity of the energy generator.

There may be more than one energy generator and/or energy consumer. In this case, the carbon intensity of the energy generated may be determined by calculating the weighted average of a plurality of carbon intensities of a plurality of energy generators, weighted based on the amount of energy generated by each of the plurality of energy generators.

The carbon intensity of the energy generated may further be averaged across a plurality of sets of matched measurements, to provide a carbon intensity score over a period of time.

The additional aspect may be combined with any one or more features of the first aspect as set out above.

The methods described herein may be performed by software in machine readable form on a tangible storage medium e.g. in the form of a computer program comprising computer program code means adapted to perform all the steps of any of the methods described herein when the program is run on a computer and where the computer program may be embodied on a computer readable medium. Examples of tangible (or non-transitory) storage media include disks, thumb drives, memory cards etc. and do not include propagated signals. The software can be suitable for execution on a parallel processor or a serial processor such that the method steps may be carried out in any suitable order, or simultaneously.

This application acknowledges that firmware and software can be valuable, separately tradable commodities. It is intended to encompass software, which runs on or controls “dumb” or standard hardware, to carry out the desired functions. It is also intended to encompass software which “describes” or defines the configuration of hardware, such as HDL (hardware description language) software, as is used for designing silicon chips, or for configuring universal programmable chips, to carry out desired functions.

The preferred features may be combined as appropriate, as would be apparent to a skilled person, and may be combined with any of the aspects of the invention.

### BRIEF DESCRIPTION OF THE DRAWINGS

Embodiments of the invention will be described, by way of example, with reference to the following drawings, in which:

FIG. 1 is a schematic diagram of a system according to the invention;

FIG. 2 is a schematic diagram of different graphs of measured energy generation;

FIG. 3 is a schematic diagram of the system according to the invention;

FIG. 4 is a schematic diagram of a stored databased or directed acyclic graph according to the invention;

FIG. 5 is a schematic diagram of a virtual interface according to the invention; and

FIG. 6 is a flow diagram showing a method according to the invention.

Common reference numerals are used throughout the figures to indicate similar features.

### DETAILED DESCRIPTION

This application relates to a system and method for performing accurate and reliable energy tracking in an energy network or electrical grid.

The system for performing energy tracking can be added to an existing energy network. The terms ‘energy network’ and ‘electrical grid’ are used here interchangeably.

The system can be used to track green energy, whereby green energy is energy that is generated with low carbon-dioxide emissions. The system is capable of tracking, storing and outputting useful parameters such as an energy excess (surplus) or energy deficit, by comparing energy generated (supply) and energy consumed (demand). The comparing of energy generated against energy consumed occurs based on recorded data that is measured and recorded in real-time, at high frequency. Data points in the recorded data are matched to each other to create a dataset. The matched dataset can be considered a linked group of data or set of matched measurements. This dataset may be stored in a relational database. The useful parameters include carbon content, also referred to as real-time carbon content, meaning the mass of carbon-dioxide attributed to energy consumption; carbon intensity, also referred to as consumer carbon intensity and carbon intensity score, referring to the amount of carbon-dioxide per unit of energy/power generated; and an energy mix, also referred to as a proportion or percentage of energy generated.

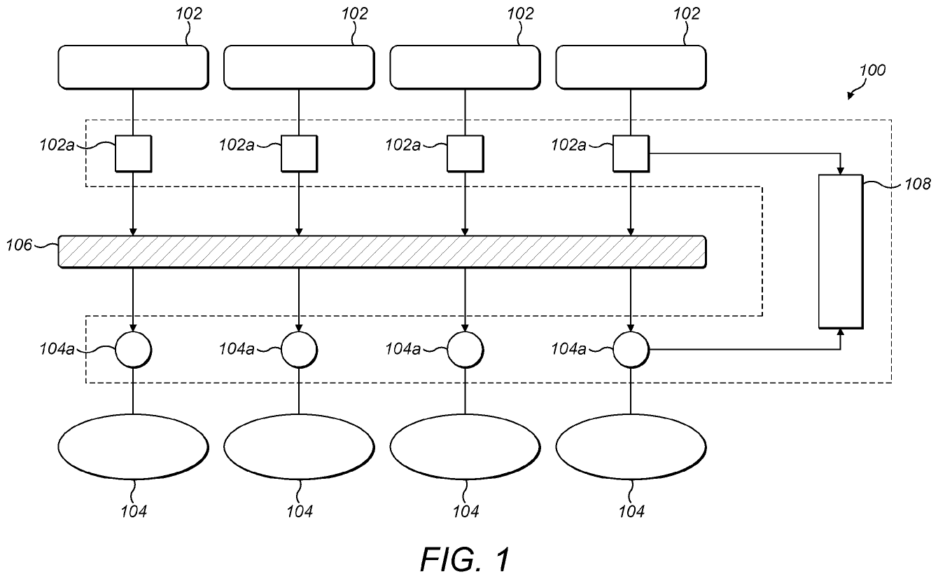

FIG. 1 shows a schematic diagram of an embodiment of an energy tracking system 100 operating in an electrical grid. The energy tracking system 100 includes one or more energy generator sensors 102a, one or more energy consumption sensors 104a, and a computing device 108.

The electrical grid includes one or more energy generators 102, one or more energy consumers 104, and a network 106 of connections, transmission lines, storage mechanisms and substations that deliver energy from the energy generators 102 to the energy consumers 104. In FIG. 1, there is a plurality of energy generators 102 and energy consumers 104.

The energy generator sensors 102a directly measure the energy generated at each respective energy generator 102. The energy consumption sensors 104a directly measure the energy consumed by each energy consumer 104. Measurements taken by the energy generator sensors 102a and the energy consumption sensors 104a are sent to the computing device 108 for processing.

The energy generators 102 being monitored by the energy generation sensors may include any type of energy generator. In an example, the energy generators 102 include at least one type of renewable energy generator, such as a solar energy generator, a wind energy generator, a tidal energy generator, a hydro-electrical energy generator or the like. The energy generator 102 may be a nuclear energy generator, or a conventional energy generator such as a gas or coal driven energy generator.

The energy generator sensors 102a are configured to measure at least the energy generated by the energy generator 102 that is provided to the electrical grid. The energy generator sensors 102a are configured to detect and measure the energy generated by the energy generator 102 in real-time, to provide continuous data reflecting the energy output of the energy generator 102. The energy generator sensors 102a may be a power meter or smart meter capable of sensing at high frequency (≥1 Hz). The energy generator sensors 102a are configured to provide data in energy generator data packets of a preconfigured format to the computing device 108. The energy generator data packets may be assembled and transmitted directly by the energy generator sensors 102a, or alternatively may be formed by respective computing devices connected to, or incorporated with the energy generator sensors 102a. For example, a smart meter or power meter usually includes a computer that is programmable, and can thus be programmed to provide data in data packets according to the preconfigured format. Additionally or alternatively, a software or hardware plugin can be included in the energy generator sensors 102a to capture the raw sensor data and use this to produce the energy generator data packets according to the preconfigured format. In this way, the system may use existing energy generator sensors 102a to collect data in real-time and provide the energy generator data packets in the required format. Alternatively still, data may be received at the computing device 108 and then translated or augmented such that it is stored in the preconfigured format as an energy generator data packet. The energy generator data packets comprise a measurement or reading from the energy generator sensor 102a of an energy generated by the energy generator, and associated generator metadata including a measurement time, indicating the time at which the measurement or reading was performed by the energy generator sensor 102a. The measurement time may be referred to as temporal metadata. The energy generator data packets may further include additional metadata. The additional metadata may include at least one or more of: an indication of the energy generator for which the measurement was taken; an indication of a specific component or part of the energy generator for which the measurement was taken; an identification associated with the energy generator, such as an owner, a company or name; an activity associated with the energy generator at the time at which the measurement was taken; and further ancillary sensor data. The additional metadata may be added at the energy generator sensor 102 and/or at the computing device 108 to form the energy generator data packet in the preconfigured format.

An activity associated with the energy generator may be an action performed on or by the energy generator at the time the measurement was taken. For example, an energy generator may be under repair, in a shut-down or low-output state; in a maintenance state or in an active energy-generating state. The activity may thus be generating energy. Where the energy generator is a photovoltaic plant, for instance, an activity performed on the photovoltaic plant may be ‘cleaning’; whereby the Photovoltaic Modules (PVM) are undergoing an automatic or manual cleaning maintenance operation. Further ancillary sensor data included in metadata may include environmental parameters such as temperature at the energy generator; humidity; irradiance of sunlight; wind direction; wind speed; precipitation and the like. Where ancillary sensor data is included in the metadata of the energy generator data packets, the energy generator packets are produced by a respective computing device connected to the energy generator sensor 102a, or by the computing device 108. The respective computing device is connected to the energy generator sensor 102a and any one or more ancillary sensors configured to provide the ancillary sensor data. The respective computing device is configured to use and collate this information to provide the energy generator data packet to the computing device 108 of the system 100. Alternatively the one or more ancillary sensors provide ancillary sensor data directly to the computing device 108. The ancillary sensor data may then be incorporated in an energy generator data packet formed at the computing device 108. In this case, the ancillary sensor data may be matched to the energy generator measurement data based on temporal metadata and any further additional metadata such as location of the ancillary sensor and an identity of an energy generator. As noted above, the energy generator data packet is constructed, at the computing device 108 to be in the preconfigured format.

If any of the measurement data or associated metadata is not in the preconfigured format, the respective computing device is configured to translate or otherwise reformat the data and associated metadata such that it is in the pre-configured format for sending in the energy generator data packet to the computing device 108. The data may be reconfigured into the pre-configured format by means of an augmentation process that is performed at the energy generator sensor 102a, a respective computing device connected to or incorporated with the energy generator sensor 102a, or the computing device 108. The pre-configured format is discussed in more detail later.

Whilst the energy generator sensors 102a are configured to measure energy generated by the energy generators 102, to provide energy generator data packets to the computing device 108, the energy consumption sensors 104a are configured to perform a similar function with respect to the energy consumers 104. In particular, the energy consumption sensors 104a are configured to measure at least the energy consumed by the energy consumer 104 from the electrical grid. The energy consumption sensors 104a are configured to detect and measure the energy consumed by the energy consumer 104 in real-time, to provide continuous data reflecting the energy demand of the energy consumer 104. The energy consumption sensors 104a may be smart meters. The smart meters are configured to detect and transmit energy consumption data in real-time at a high frequency (≥1 Hz). The energy consumption sensors 104a may be configured to transmit data in the preconfigured format. The energy consumption sensors 104a are configured to provide data in energy consumption data packets of the preconfigured format to the computing device 108. The energy consumption data packets may be assembled and transmitted directly by the energy consumption sensors 104a, or alternatively may be formed by respective computing devices connected to the energy consumption sensors 104a. The energy consumption data packets comprise a measurement or reading from the energy consumption sensor 104a of an energy consumed by the energy consumer 104, and associated consumer metadata including a measurement time, indicating the time at which the measurement or reading was performed by the energy consumption sensor 104a. The measurement time may be referred to as temporal data. The energy consumption data packets may further include additional metadata. The additional metadata may include at least one or more of: an indication of the energy consumer for which the measurement was taken; an indication of a specific component or part of the energy consumer for which the measurement was taken; an identification associated with the energy consumer; such as an owner, a company or name; a location of the energy consumer 104; an activity associated with the energy consumer 104 at the time at which the measurement was taken; and further ancillary sensor data.

An activity associated with the energy consumer may be an action performed by the energy consumer 104 at the time the measurement was taken. For example, an energy consumer 104 may perform an energy-consuming action such as turning on a light, an electrical appliance, or an electrical system at the energy consumer 104. Further ancillary sensor data included in metadata may include parameters such as light level at the energy consumer 104 and temperature at the energy consumer 104. Where ancillary sensor data is included in the metadata of the energy consumer data packets, the energy consumer data packets are produced by a respective computing device connected to the energy consumption sensor 104a. The respective computing device is connected to the energy consumption sensor 104a and each of the ancillary sensors configured to provide the ancillary sensor data. The respective computing device is configured to use this information to provide the energy consumption data packet to the computing device 108 of the system 100.

If any of the measurement data or associated metadata is not in the preconfigured format, the respective computing device is configured to translate or otherwise reformat the data and associated metadata such that it is in the pre-configured format for sending in the energy consumption data packet to the computing device 108. The pre-configured format is discussed in more detail later.

The computing device 108 is configured to receive and store the energy consumption data packets and the energy generator data packets from the energy consumer 104 and the energy generator 102 respectively. At the computing device 108, the energy consumption data packets and the energy generator data packets are matched to each other according to their temporal data. In particular, if an energy generator data packet includes temporal data that indicates a system time or time of day that matches that of an energy consumption data packet, the computing device 108 is configured to link these specific data packets such that a relationship is formed between the data packets. This may be implemented in several ways. In one example, the link between data packets is a shared time-stamp of one or more data packets. Each data packet is assigned a packet identifier (ID) which may be a unique number, string or the like. The link is maintained or stored in a relational database by storing together the IDs of the linked data packets. Other ways of storing the linked data packets may also be implemented as a person skilled in the art would understand.

More than one energy generator data packet may be linked to an individual energy consumption data packet, and similarly more than one energy consumption data packet may be linked to an individual data energy generator packet. Thus, the computing device 108 may form links between multiple energy generator data packets and multiple energy consumption data packets depending on the temporal data of these data packets. Furthermore, energy generator data packets may be linked to other energy generator data packets according to their temporal data, and similarly energy consumption data packets may be linked to other energy consumption data packets according to their temporal data. This is likely to happen when there is more than one consumer 104 and energy generator 102 being measured in the system 100.

For example, a first energy generator sensor may provide, to the computing device 108, a first energy generator data packet indicating a measurement of 1.527 kWh generated by a first energy generator at a time of 07:04:14 on 20 Feb. 2022. In this example, the time and date represent the temporal data of the energy generator sensor data packet. A second energy generator sensor, associated with a second energy generator, may provide a second energy generator data packet indicating a measuring of 0.473 kWh generated by the second energy generator at a time of 07:04:14 on 20 Feb. 2022. When the computing device 108 receives the first and second energy generator packets, the temporal metadata of said packets are compared. Since the time and date, and thus the temporal metadata, of the second energy generator packet matches that of the first energy generator packet, the computing device 108 if configured to link the first and second energy generator packets together. A first energy consumption sensor may also provide a first energy consumption data packet, indicating a measurement of 0.5 kWh consumed at a time of 07:04:14 on 20 Feb. 2022. In this case, the first energy consumption data packet is linked with the first and second energy generation data packets based on the matching temporal metadata.

By using real-time sensing at both the energy generator end and the consumer end of the system, it is ensured that the computing device 108 receives data packets that correspond to a continuous stream of measured data from both the energy generator end and the consumer end. This means that data can be linked in a continuous manner such that there are no discrete time jumps in energy generation or consumption measurements. In other words, performing frequent, real-time measurements of energy generated and energy consumed by the sensors allows the computing device 108 to account for energy in the system 100 at very narrow time intervals (such as a second or less) rather than longer discrete time periods (for example, half an hour).

As discussed above, it is not possible to accurately match energy consumption data to energy generation data when the data is collected over longer discrete time periods. In particular, measuring data in longer time periods increases the probability of false-matches between energy consumed and energy generated, leading to inaccurate generation and consumption statistics. For example, although energy generated may appear to match energy consumed over a longer discrete time period, the energy may be generated at a time that is different to the time the energy is consumed within the time period. In this case there is an energy mismatch, since the energy generated is not the same energy that is consumed. By using frequent real-time data, these problems are negated, and the computing device 108 is able to effectively store energy generation and consumption measurements that provide an instantaneous snapshot of the system 100 at a particular moment in time.

It is to be understood that the real-time sensing of the energy generator sensor 102a and the energy consumption sensor 104a occurs at a high frequency. For example, real-time sensing may occur at 1 Hz, 5 Hz or faster. For example, sensing may occur at 1-100 Hz. The real-time aspect of the sensing describes how frequently and immediately sensor measurements are made and stored. ‘Real-time’ is considered to include any lag-time required to perform these operations computationally. The frequency of sensing and storing measurement data and associated temporal metadata is preferably at a rate that is equal or more frequent than 1 Hz. However, it is to be understood that the frequency of measuring and storing measurement data may be extended to a measurement per minute, 2 minutes, and up to a measurement every 5 minutes without losing the benefits of the system and method described herein. Energy generator measurements and energy consumption measurements may be performed at a frequency according to the constraints or attributes of the energy generators 102. One such constraint may be the ramp-up time of the energy generator 102 being monitored. For example, as a gas generator may have a ramp-up time of approximately 10 seconds. In order to ensure that energy measurements are collected from the gas generator in an accurate and precise manner, (such that the ramp-up is not missed) the frequency of real-time measurements should be equal or quicker than one measurement every 10 seconds (0.1 Hz). Thus, whilst it is preferable that measurements are taken at frequencies greater than 1 Hz, it is also possible to take measurements between once a second and once every 5 minutes.

The links between the data packets may be established by any appropriate means, for example, by using a linked relational database, adding relationship metadata to each data packet, and/or by storing data packets with or according to their linked data packets. Data packets that share a link may be referred to as a linked group of data. There are plurality of linked groups of data, each corresponding to different moments in time.

It is to be understood that, whilst the energy generator sensor 102a and the energy consumption sensor 104a are configured to operate in real-time, taking frequent measurements of energy generated and energy consumed, it is not necessary, and is thus optional, that the data packets including the measurement data are sent to the computing device 108 in real-time, and/or that the computing device 108 match the measurements in real-time. In some embodiments, data packets may be sent after a period of time from the time of measurement, and/or may be stored locally at the sensor or at a respective computing device before being sent to the computing device 108 at predetermined intervals. In this way, the data packets may be sent to the computing device 108 in batches. Similarly, the computing device 108 may perform the steps of comparing the received data packets and matching the data packets at predetermined intervals. Performing the processing of the sensor measurement data in this way, rather than in real-time, can increase both the communication efficiency of the system, since the sensors/computing device 108 may be configured to send/receive at fixed intervals, meaning communication is not required to be constantly active between the sensors and the computing device 108; and the power/computational efficiency of the computing device 108, since matching need only be performed during the predetermined intervals. Effectively, the system 100 is able to process data a period of time after it is obtained/measured in order to optimise the efficiency of said processing. Since the measurements themselves are performed in real-time, and the data packets including the measurements also include temporal metadata indicating the time of measurement, the real-time nature of the data is preserved even if it is subsequently processed at a later time. The comparing and matching of data by the computing device 108 may therefore include comparing and matching historic data packets.

After the computing device has matched one or more data packets (energy generator and/or energy consumption data packets) to form at least one linked group of data, the computing device 108 is configured to further process the linked group of data to compare the energy generated to the energy consumed within said linked group of data.

Firstly, a comparison between the energy generated and the energy consumed is performed on the linked group of data, to determine the presence of either an energy deficit or an energy excess. An energy deficit exists when the sum of the energy generated is less than the sum of the energy consumed. An energy excess exists when the sum of the energy generated is greater than the sum of the energy consumed. Thus, measurements from energy generator data packets in the linked group of data are summed, and the measurements from energy consumption data packets in the linked group of data are summed. These two sums are then compared to each other. The difference results in an energy deficit or energy excess. The computing device 108 may output data indicating the presence and magnitude of the energy deficit or excess. The energy consumption data packets correspond to consumed energy measurements from one or more particular consumers 104. Thus, the calculation of an energy excess or energy deficit relates directly to the consumption of the one of more particular consumers 104. This means that the first processing to determine the energy excess or energy deficit effectively provides a measure of how much energy the one or more particular consumers 104 are consuming against the energy being generated by the monitored energy generators 102. Since measurements are performed at high frequency in real-time, the measure is a real-time measure of consumer energy consumption against energy generation. This real-time measure can be used according to the further processes below to identify and attribute energy generated from particular generators 102 to particular consumers 104; as well as to calculate a carbon intensity of energy consumed for each consumer 104. These further processes are discussed in more detail later.

Following on from the example above, a linked group of data, associated with temporal metadata of 07:04:14 on 20 Feb. 2022, may comprise the first energy generator data packet indicating a measurement of 1.527 kWh generated by a first energy generator, the second energy generator data packet indicating a measuring of 0.473 kWh generated by a second energy generator, and the first consumption data packet indicating a measurement of 0.5 kWh consumed. Performing the comparison above on this example would include summing the energy generated (1.527+0.473=2 kWh); and comparing the sum of the energy generated with the sum of the energy consumed (2 kWh−0.5 kWh=1.5 kWh excess). Thus, in this example, the computing device 108 would compare the energy generated to the energy consumed and determine a result that an excess of 1.5 kWh exists for the linked group of data. The computing device 108 is configured to store the result of this comparison in memory associated with the linked group of data.

When it is determined that an energy excess exists, meaning more energy is generated by the energy generator 102 than consumed by the energy consumer 104, the computing device 108 may output or store data indicating the excess. This data may then be used to offer the excess generated energy to the grid on the balancing market or to sell to a third party as part of a special purpose power purchase agreement. Alternatively the excess energy is curtailed to the grid.

Following the determination of an energy deficit, a proportion of energy required from other sources on the electrical grid to compensate for the deficit is determined. Usually, this proportion is equal to the deficit. Expanding the example above, if the linked group of data includes a second energy consumption data packet of 3.5 kWh having the same temporal metadata of 07:04:14 on 20 Feb. 2022, then the sum of energy consumed is equal to 4 kWh whilst the sum of the energy generated is only 2 kWh. This means that a deficit of 2 kWh exists. Thus, the computing device 108 is configured to determine, that in order to compensate for the deficit, 2 kWh of energy is required from the electrical grid, equating to a 50% proportion of the sum of energy consumed. The proportion of energy consumed that is sourced from the electrical grid may be stored in memory and associated with the linked group of data.

In some embodiments, the energy tracking system 100 is used to track how ‘green’ a consumer's energy consumption is, by introducing a measure of the carbon footprint of the consumer's energy consumption into the method and system for tracking energy. In particular, the method and system may introduce the measure of tracking a ‘carbon intensity’, of energy consumption, measured as CO2 in g CO2e/kWh. To introduce this measure, the carbon intensity of energy generated at the energy generators 102 is determined or retrieved, and a process of attributing energy consumed for each individual consumer 104 to one or more specific energy generators 102 is performed. From knowledge of these two variables (the carbon intensity at the generator 102 side and the attribution of where consumed energy is generated), it is possible to determine the carbon intensity, also referred to as a ‘carbon intensity score’ for each energy consumer 104. This process will now be explained in more detail.

The energy generators 102 that are monitored may include renewable (green) energy generators and non-green energy generators. Renewable energy generators 102 monitored by the energy generator sensors 102a may include generators 102 such as solar, wind, tidal or hydro-electric plants. Energy generated from these generators 102 may be considered to have no carbon intensity, (a carbon intensity of zero, 0 g CO2e/kWh) or a predetermined carbon intensity indicative of the relative carbon-cost for manufacture, maintenance and the like of each of these generators 102 per unit of energy produced. For example, a wind energy plant may be attributed a carbon intensity score of 1 g CO2e/kWh, corresponding to set-up and maintenance carbon costs.

Non-renewable energy generators 102 that are being monitored may be associated with higher carbon intensity scores (e.g. 100 g CO2e/kWh).

The carbon intensity score for each energy generator 102 may be provided by the energy generator 102 to the computing device 108 and stored in memory, associating each known monitored energy generator 102 with a corresponding carbon intensity score. Alternatively, the carbon intensity score for each generator may be measured at the energy generator 102 using various scientific techniques, or may be estimated based on the type of the energy generator 102.

Energy generated from outside of the monitored energy generators is assumed to come from the electrical grid. The carbon intensity of energy from the electrical grid, effectively outside of the system 100, is calculated using an estimated or imported grid carbon intensity from data reports provided by an external data provider. For example, the electrical grid's energy mix report is periodically imported to the computing device 108, to identify or otherwise calculate, from the report, the grid carbon intensity of the electrical grid at the time associated with the linked group of data. The grid carbon intensity of the electrical gird may be provided in g CO2e/kWh for every kWh of energy provided by the electrical grid, or could be stated as g/kW (gram of carbon per amount of power every second), for example.

Once the carbon intensity scores for each of the monitored energy generators 102 is known and stored in the computing device 108, and the carbon intensity of the electrical grid is known and stored, the carbon intensity of energy consumption of the energy consumer 104 can be established by the computing device 108. For each linked group of data, corresponding to matched energy generator and/or energy consumption data packets, the carbon intensity scores of each energy generator represented in the linked group of data are averaged according to the proportion of energy provided by each energy generator 102 to the linked group of data. This includes any contribution from the electrical grid. In particular, where there is an energy deficit, meaning energy consumption is greater than the energy generated in the linked group of data, the electrical grid is determined to compensate for the deficit.

Following on from the above example, whereby the linked group of data includes a first energy generator measurement of 1.527 kWh generated by a first energy generator, a second energy generator measurement of 0.473 kWh generated by a second energy generator, a first energy consumption measurement of 0.5 kWh consumed by a first consumer, and a second energy consumption measurement of 3.5 kWh consumed by a second consumer, the sum of energy consumed is equal to 4 kWh whilst the sum of the energy generated is only 2 kWh. This means that a deficit of 2 kWh exists. Assuming the first and second energy generators 102 are renewable energy generators with an attributed carbon intensity of 0 g CO2e/kWh for energy generated by these energy generators, and the grid carbon intensity is 100 g CO2e/kWh, the carbon intensity of energy consumption can be calculated for the linked group of data. In particular, the carbon intensity of consumed energy is equal to the weighted average of the carbon intensities of generated energy, weighted according to the energy generated by each of the respective sources of generated energy. Thus, the carbon intensity of consumed energy is (100 g CO2e/kWh×2 kWh+0 g CO2e/kWh×1.527 kWh+0 g CO2e/kWh×0.473 kWh)/4 kWh=50 g CO2e/kWh. The carbon intensity of consumed energy may be referred to as a consumer carbon intensity.

The consumer carbon intensity is stored at the computing device 108 with respect to the linked group of data. Since the consumer carbon intensity is calculated based on real-time energy generator measurements and real-time energy consumption measurements in the linked group of data, the consumer carbon intensity calculated for the linked group of data also represents a real-time measure of the carbon intensity for the specific time to which the linked group of data corresponds.

The consumer carbon intensity may be subject to further processing to determine further parameters of the energy consumption of each energy consumer. In particular, the consumer carbon intensity may be used to calculate a carbon content for the linked group of data. The carbon content effectively indicates the mass of carbon attributed to the energy consumed by each consumer. The carbon content is measured in g or kg. To determine the carbon content for each consumer represented in a linked group of data, the consumer carbon intensity is multiplied by the energy consumed for each consumer.

Following on from the above example, wherein the consumer carbon intensity for consumers represented in the linked group of data is 50 g CO2e/kWh, and the linked group of data includes a first energy consumption measurement of 0.5 kWh consumed by a first consumer, and a second energy consumption measurement of 3.5 kWh consumed by a second consumer, the carbon content of each consumer is calculated as: 50 g CO2e/kWh×0.5 kWh=25 g for the first consumer; and 50 g CO2e/kWh×3.5 kWh=175 g for the second consumer.

Another way of determining the carbon content per consumer 104 is to split the total real-time carbon content according to the relative proportions of energy consumed. In this example, assuming that the energy generators 102 represented in the linked group of data have a carbon intensity of energy generation of 0 g CO2e/kWh, the computing device 108 may be configured to compute the total real-time carbon content of the energy consumed by the consumer 104 by multiplying the grid carbon intensity of the electrical grid by the energy deficit. In this example, the real-time carbon content is 2 kWh multiplied by 100 g CO2e/kWh which equals 200 g carbon. The first energy consumption data packet of 0.5 kWh equates to 0.5/4 or 12.5% of the total energy consumed, whilst the second energy consumption packet of 3.5 kWh equates to 3.5/4 or 87.5% of the total energy consumed. As such, in the example, the computing device 108 is configured to split the 200 g of real-time carbon content such that 12.5% of the total real-time carbon content is attributed to the energy consumer 104 associated with the first energy consumption data packet as a first real-time carbon content portion, and such that 87.5% of the total real-time carbon content is attributed to the energy consumer 104 associated with the second energy consumption data packet as a second real-time carbon content portion. According to this processing, the first real-time carbon content portion equals 25 g of carbon whilst the second real-time carbon content portion equals 175 g of carbon, on the basis that the total real-time carbon content is 200 g of carbon.

This total real-time carbon content and/or the real-time carbon content per consumer 104 is stored and associated with the linked group of data. The carbon content refers to the mass of carbon dioxide attributed to the energy consumed by the energy consumer 104. Since the carbon content is calculated for the linked group of data, which includes real-time energy generator and/or real-time energy consumption measurements, the carbon content is also a real-time measure of the carbon corresponding to energy consumed by a particular consumer at the time represented by the linked group of data.

If energy generators, conventional or renewable, have a non-zero carbon intensity associated with their respective energy generation as discussed above, the computing device 108 is configured to calculate the real-time carbon content by including contributions from the energy generated by the energy generators. For example, the first and second energy generators may be associated with a predetermined carbon content of 2 g CO2e/kWh. In this case, the real-time carbon content is 200 g carbon from the electrical grid plus 4 g (2 kWh×2 g CO2e/kWh) of carbon from the first and second energy generators 102, meaning a total 204 g of carbon is used for the 4 kWh of energy consumed.

It is to be understood that including such contributions from the energy generators 102 is optional, and may be alternatively approximated as providing 0 g of carbon contributions, such that the only carbon contributions comes from energy used from the electric grid. It is also to be understood that the carbon intensity for the energy generators 102 may be set differently according to the type of energy generator, such that the carbon intensity of energy generation of solar energy is different to that of wind, for example. Furthermore, non-green energy generators 102 such as coal, nuclear and gas energy generators may also be monitored using energy generator sensors 102a as discussed above. In this case, the real-time carbon content may also take into account measurements and data from these non-green energy generators.

Further processing may be performed on the linked group of data to determine parameters for individual consumers. As noted above, the consumer carbon intensity is calculated for the linked group of data as a whole. The carbon content for each consumer is then derived from the carbon intensity of the linked group of data and the energy consumed per consumer. In some instances, the linked group of data includes energy consumption measurements from more than one consumer, or in other words, data from more than one energy consumption sensors 104a is matched in the process of matching to form the linked groups of data. It is possible to attribute energy consumption and thus carbon consumption to the consumers 104 associated with the consumed energy. In particular, where the linked group of data includes energy consumption measurement data from more than one consumer 104, the real-time carbon content and carbon intensity score may be calculated for each consumer 104 based on their relative consumption of energy in the linked group of data.

In some embodiments, the estimated or imported carbon intensity of the electrical grid may be dependent on the consumer 104 associated with the energy consumption data packets included in the linked group of data. This may occur if the consumer 104 in question has or is associated with a specific ‘alternative supplier’ to the energy generators 102 that are monitored by the energy generator sensors 102a. In this case, the carbon intensity of the grid may be selected or imported by the computing device 108 directly from the alternative supplier. The alternative supplier and/or an operator may provide, to the computing device 108, the carbon intensity, or the computing device 108 may be configured to estimate the carbon intensity of the alternative supplier based on retrieved data.

Where there is a plurality of energy consumers 104 associated with energy consumption data packets in the linked group of data, each energy consumer 104 may be associated with a separate alternative supplier. Each separate alternative supplier may be associated with a different carbon intensity, such that it would not be accurate for a single carbon intensity to be used to calculate the real-time carbon content and/or carbon intensity score for each energy consumer 104. In this case, the computing device 108 may, before calculating the real-time carbon intensity score or carbon content for each consumer, split the determined energy deficit into energy deficit portions according to relative proportions of energy consumption of each of the energy consumers 104 associated with the energy consumption data packets in the linked group of data. Following the above example, the first energy consumption data packet of 0.5 kWh equates to 0.5/4 or 12.5% of the total energy consumed, whilst the second energy consumption packet of 3.5 kWh equates to 3.5/4 or 87.5% of the total energy consumed. The deficit is 2 kWh as calculated above. Assuming that the first and second energy consumption data packets correspond to a first and a separate second energy consumer 104, the deficit of 2 kWh is split into a first deficit portion of 0.125×2=0.25 kWh corresponding to the portion of the deficit attributed to the first energy consumer, and a second deficit portion of 0.875×2=1.75 kWh corresponding to the portion of the deficit attributed to the second energy consumer.

The first and second energy consumers may have different alternative suppliers. The first energy consumer may have a first alternative supplier, having a carbon intensity for energy supplied equal to 300 g CO2e/kWh, whilst the second energy consumer may have a second alternative supplier having a carbon intensity for energy supplied equal to 50 g CO2e/kWh. Using this information, the computing device 108 is configured to calculate individual real-time carbon intensity scores and/or real-time carbon contents for the energy consumed by each of the first and second energy consumers. In particular, the carbon intensity score is calculated per consumer rather than for the linked group of data as noted above. Thus, for the first consumer, the carbon intensity is calculated by averaging the carbon intensity from all energy generator sources (including the first alternative supplier), weighted by the relative differences in energy generation between these sources and dividing by the energy consumed by the first consumer. The first alternative supplier term in the calculation is weighted by the first deficit portion calculated as above. This means that the first consumer is assumed to obtain their share of the energy deficit from the first alternative supplier. In the above example, the carbon intensity for the first consumer is thus: (300 g CO2e/kWh×0.25 kWh+0 g CO2e/kWh×1.527 kWh+0 g CO2e/kWh×0.473 kWh)/0.5 kWh=150 g CO2e/kWh. Similarly, the individual carbon intensity for the second consumer is equal to the weighted average of the carbon intensities of all energy generator sources (including the second alternative supplier). Thus, in the above example, the carbon intensity for the second consumer is: is (50 g CO2e/kWh×1.75 kWh+0 g CO2e/kWh×1.527 kWh+0 g CO2e/kWh×0.473 kWh)/3.5 kWh=25 g CO2e/kWh.

The real-time carbon content may be calculated using the calculated carbon intensities, by multiplying the carbon intensities by the energy consumed per consumer. For example, the first energy consumer consumes energy with a carbon content of 150 g CO2e/kWh×0.5=75 g CO2e. The second energy consumer consumes energy with a carbon content of 25 g CO2e/kWh×3.5=87.5 g CO2e. In this case, although the second consumer is responsible for a higher carbon content than the first consumer, the carbon intensity score for the second consumer is much lower than that of the first consumer.

Alternatively, the carbon content of the consumers may be calculated without directly calculating the carbon intensity scores of each consumer. In this way, the carbon content of the first consumer is calculated by multiplying the first deficit portion by the carbon intensity for the first alternative supplier. This is 0.25 kWh×300 g CO2e/kWh=75 g CO2e. The real-time carbon content for the second consumer is calculated by multiplying the second deficit portion by the carbon intensity for the second alternative supplier. This is 1.75 kWh×50 g CO2e/kWh=87.5 g CO2e.

Thus, in this manner, it is possible to approximate the real-time carbon intensity and/or carbon content for each energy consumer associated with the linked group of data individually, based on their associated alternative suppliers. It is noted that this method assumes that the energy generation is shared proportionately to energy consumption, such that the energy deficit is shared proportionately to energy consumption.

However, there are different methods to attribute energy deficits. For example, where there is more than one consumer 104, the consumers 104 may be provided with energy from monitored energy generators 102 according to a priority listing. In this example, green electricity (electricity from renewable sources) may be provided or assumed to be provided according to the priority listing such that a consumer 104 with a higher priority is able to consume more or a larger share of green electricity than a consumer with a lower priority in the priority listing. The priority listing is stored at the computing device 108 and may be pre-agreed with the plurality of consumers. The energy deficit may then be calculated for each consumer 104 on the basis of the priority listing. The priority listing may allow a threshold amount of green energy to be consumed per consumer in the priority listing. Once the threshold amount is provided, the green energy may be provided to the next consumer in the priority listing until all green energy is consumed, or may be provided in an equal way to lower priority consumers. Alternatively, green energy may be provided to the highest priority customer until their demand is met, before iteratively moving to the next-highest priority customer.

It is to be understood that the carbon intensity score may itself be a real-time parameter, calculated for each linked group of data, or the carbon intensity score may be a score that is averaged across a plurality of linked groups of data.

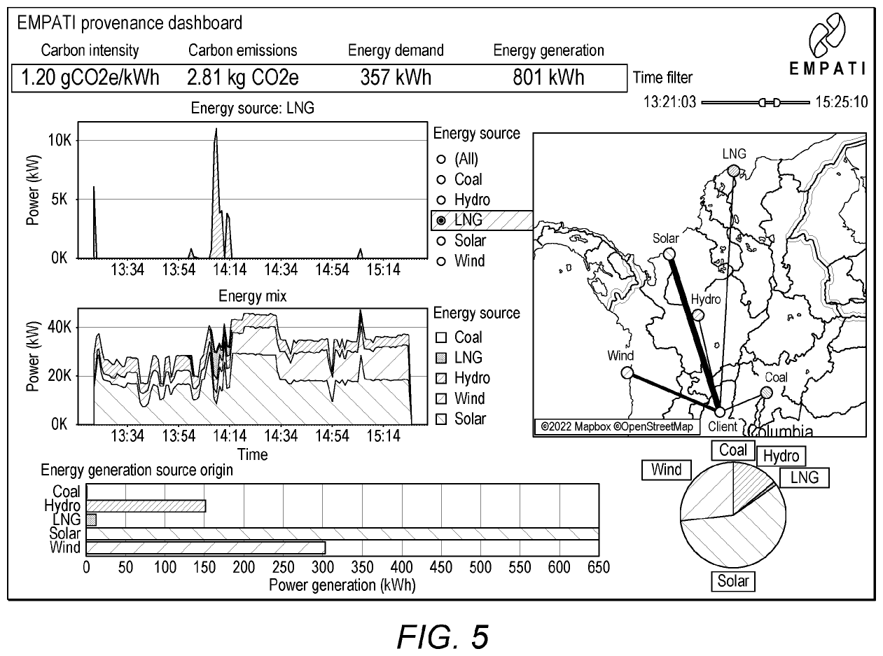

The carbon intensity score is output by the computing device 108, for storage on a database, display to an operator, consumer or other user, or via a communications network to a further device. The carbon intensity score effectively provides a measure indicative of how green/brown an individual consumer's energy consumption is. The carbon intensity score may thus serve as a basis for further processing, to determine whether an action is required to be taken to reduce the carbon intensity of energy consumption for the energy consumer 104. In particular, the computing device may be configured to compare the real-time carbon intensity score per linked group of data, or an overall carbon intensity score, averaged over a period of time including a plurality of linked groups of data, to one or more carbon intensity thresholds. The one or more carbon intensity thresholds may be set by the consumer 104, an energy provider, grid operator or the like as desired, to define an upper acceptable limit to carbon intensity for the energy consumption of the individual consumer 104. For example, the carbon intensity threshold may be set by the consumer at 100 g CO2e/kWh, 200 g CO2e/kWh, 500 g CO2e/kWh, 1 kg CO2e/kWh or the like. Alternatively or additionally, a carbon intensity threshold may be set by the system 100. The one or more carbon intensity thresholds are stored by the computing device 108. The determined carbon intensity score is compared to the one or more carbon intensity thresholds, in real-time or periodically, by the computing device 108. If or when the determined carbon intensity score matches or passes a carbon intensity threshold, the computing device 108 is configured to perform a responsive action. The responsive action is dependent on the type of carbon intensity threshold that is matched or passed. When the carbon intensity threshold that is passed is set by the consumer, the responsive action may include sending, from the computing device 108, a notification, message, and/or alarm to the consumer 104 or a device associated with the consumer 104 to indicate that the carbon intensity threshold has been passed. The notification, message and/or alarm may further instruct the consumer 104 to reduce energy consumption, and/or may instruct the consumer 104 to access the database associated with the computing device 108 storing the linked group of data and associated processing and calculations. From this database, the consumer 104 is able to see how their individual energy consumption varies across a time period, such that corrective analysis and decisions can be made by the consumer 104 to adjust their energy consumption habits to reduce the carbon intensity score. An example of data from a database accessible by the consumer 104 is provided in FIG. 5 as described later.

When the carbon intensity threshold that is matched or passed by the carbon intensity score is set by the system 100, the responsive action may include sending, from the computing device 108, a notification, message, or alarm to one or more energy generators 102. The notification, message or alarm may indicate to the generator 102 or an operator of the generator 102 to perform a control action related to the energy generator 102, such as to increase energy generation, to modify one or more parameters of the energy generator 102, and/or to perform a corrective action. For example, the computing device 108 may send an instruction to a hydro-electric energy generator 102 to start providing hydro-electric power or increase hydro-electric power generation to reduce the carbon intensity score. A further responsive action that may be performed is requesting, by the computing device 108, energy to be provided from energy storage facilities to compensate for the current energy deficit and reduce the carbon intensity score below the carbon intensity threshold. For example, the computing device 108 may request that energy from a battery be depleted and put onto the grid to reduce the carbon intensity score.

The linked group of data may further be processed by the computing device 108 to determine an energy mix corresponding to the consumed energy for a particular consumer associated with the linked group of data. In particular, the computing device 108 may be configured to calculate the relative and/or absolute energy consumption by type-of-generator, using both the measurements of energy consumption from one or more energy consumption data packets in the linked group of data and the measurements of energy generation from one or more energy generator data packets in the linked group of data. This includes determining, from metadata in the energy generator data packets, a type of energy generator responsible for generating the energy as indicated by the energy generation measurements of the energy generator data packets, accumulating and summing energy generation measurements corresponding to the same determined type of energy generator, determining a proportion of the total energy generated corresponding to each determined type of energy generator, and applying the determined proportions of the total energy generated to the energy consumed by each consumer, to obtain a proportion of the energy consumed by the consumer attributable to each determined type of energy generator. Following on from the previous example, wherein the linked group of data comprises the first energy generator data packet indicating a measurement of 1.527 kWh generated by a first energy generator, the second energy generator data packet indicating a measuring of 0.473 kWh generated by a second energy generator, and the first consumption data packet indicating a measurement of 0.5 kWh consumed, with no other consumers present in the linked group of data. The first energy generator data packet may include metadata indicating that the first energy generator is a ‘solar’ type energy generator. Alternatively, the metadata of the first energy generator data packet may include a name or identification associated with the first energy generator, such as an owner. The computing device 108 may be configured to identify, using this metadata, the type of the first energy generator as ‘solar’ from a look-up table or the like stored in memory, wherein the look-up table includes linked entries indicating the type of energy generator for each known identification and/or name. The second energy generator data packet may include metadata indicating that the second energy generator is of a ‘hydro-electric’ type. The computing device is configured to determine the proportion of energy per type of energy generator. In this example, 1.527 kWh/2 kWh=76.35%, which is attributed to the solar type of energy generator. Similarly, 0.473 kWh/2 kWh=23.65% which is attributed to the hydro-electric type of energy generator. Once these proportions are determined, they are applied to the energy consumed by each consumer. As such, it is assumed that 76.35% of the energy consumed originates from solar whereas 23.65% originates from hydro-electric. These represent the relative energy consumption values for type-of-generator. For the absolute values, the relative values are applied to the 0.5 kWh of energy is consumed. Therefore, 76.35% of 0.5 kWh=0.38175 attributable to solar and 0.5 kWh×23.65%=0.11825 kWh attributable to hydro-electric. The relative and/or absolute values are stored in memory and may be output by the computing device 108. The calculated absolute and/or relative mix may be expanded to all monitored energy generators 102, including any conventional energy generators, as well as the mix sourced from the electrical grid.

Alternatively, the energy generated may not be accumulated and summed according to the type of generator, but rather according to each individual energy generator 102, such that determining the energy mix as above includes determining the contribution towards energy consumed from each individual energy generator.

Any of the above processes described above may be implemented by the system to prioritise which one or more of several energy consumers 104 is provided with green electricity. For example, the carbon intensity score may be used as a means of auditing the carbon footprint of an energy consumer 104. Should the energy consumer 104 wish to reduce their carbon footprint, the system is configurable such that the consumer 104 can be re-positioned or promoted in the priority listing as discussed above, meaning they are subject to higher priority with respect to the receipt of green electricity.

Any one or more of the processing tasks above may be performed by the computing device 108. The computing device 108 is configured to store the result of said processing, and may output it, via a display, or over a communications network to a consumer 104. Alternatively, the computing device 108 may grant access to the stored data over a secure encrypted communication link using various techniques as would be understood.

Whilst the above description of processing is exemplified with respect to a single group of linked data, it is to be understood that the same processing occurs to a plurality of groups of linked data, at different instances of time. As explained above, each linked group of data includes data packets that are linked (matched) based on the temporal metadata in the data packets. The processing for each linked group of data is accumulated over a period of time. For example, consider over 5 seconds there are 5 separate groups of linked data, corresponding to 5 sets of energy generation measurements and 5 sets of energy consumptions measurements recorded by the sensors 102a and 104a in real-time at a frequency of 1 Hz. The 5 groups of linked data may be individually processed and subsequently accumulated or combined. Exemplary data showing this process is indicated in table 1 below.

TABLE 1

| | Group 1 | Group 2 | Group 3 | Group 4 | Group 5 | Total |
|---|---|---|---|---|---|---|
| Sum of green energy generated (kWh) | 5 | 7 | 7 | 4 | 4 | 27 |
| Sum Energy Consumed (kWh) | 6 | 5 | 5 | 7 | 7 | 30 |
| Excess (kWh) | −1 | 2 | 2 | −3 | −3 | −3 |
| Carbon Intensity score (g CO2e/kWh) | 16.67 | 0 | 0 | 42.88 | 42.88 | 23.33 |
| RT Carbon content (g CO2e) | 100 | — | — | 300 | 300 | 700 |

As shown in Table 1, the excess/deficit is accumulated over the five linked groups of data to determine a total deficit of 3 kWh. Similarly, the real-time carbon content is accumulated to indicate that 700 g of carbon can be attributed to the 5 seconds of energy consumption, from drawing energy from the electrical grid to meet the individual deficits of each linked group of data. The carbon intensity score is averaged over the linked group of data to provide a carbon intensity score of 20.48 g CO2e/kWh over the 5 second period.

From Table 1 it is clear to see the advantages associated with recording measurements and time of measurements by the sensors 102a and 104a in real-time and at high frequency. In particular, looking at the excess row in Table 1, it is clear that Groups 1, 4 and 5 each exhibit an energy deficit (noted by the negative excess value). As such, each of these groups are associated with a real-time carbon content (assuming carbon only originates from the electrical grid in this example). The deficit for these groups sums to 7 kWh, equating to 700 g CO2e of total carbon content. However, looking at the ‘total’ column, it would appear that the deficit over the 5 second period is only 3 kWh. If the ‘total’ column was the only data available, (i.e. if frequency of real-time measurements was 0.2 Hz), this would suggest a carbon content of 300 g CO2e, when it is in fact 700 g CO2e. Thus, it is more accurate to use higher frequency real-time measurements.

Similarly, the carbon intensity is averaged for each linked group of data over the five seconds to provide an overall carbon intensity score of 23.33 g CO2e/kWh. However, if only the ‘total’ column was used, the carbon intensity would appear to be 3 kWh×100 g CO2e/kWh/30 kWh=10 g CO2e/kWh. This illustrates the problems associated with measuring data over a longer sample time. In effect, precision and accuracy are lost. By performing the measurements in real-time and matching sets of data together according to their temporal metadata, it is ensured that processing is performed accurately and precisely, such that the true carbon content and carbon intensity over the period of time (5 seconds in Table 1) determined.

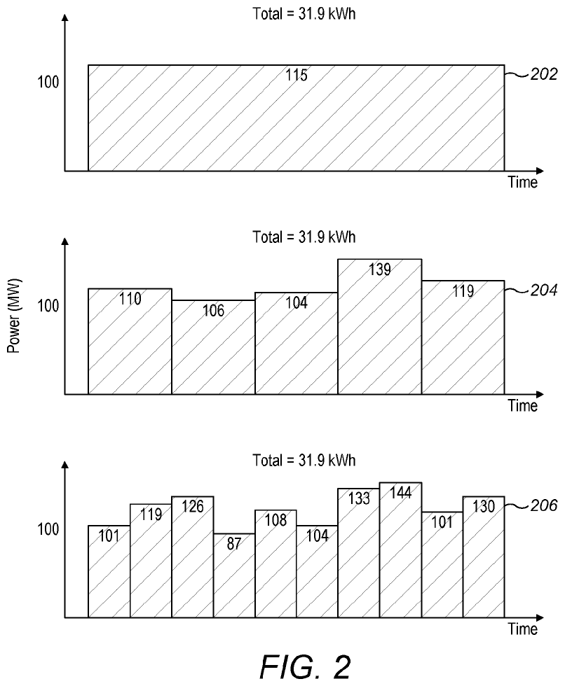

FIG. 2 illustrates this concept, and how much more useful, accurate and precise real-time energy measurements are when they are generated and stored at higher frequencies. In particular, FIG. 2 shows a series of schematic graphs including a first graph 202, a second graph 204, and a third graph 206, each displaying measured power generation in MW against time in seconds. The scale of the time axis ranges from 0 to 1s. For the first graph 202, the frequency of measurement is 1 Hz, meaning only one measurement is recorded, equating to 31.9 kWh of energy generated. The second graph 204 illustrates measurements taken at a frequency of 5 Hz, meaning five measurements are taken. As can be seen from the second graph 204, although the total energy generated is the same as the first graph 202 (31.9 kWh), the distribution of energy generation against time is not constant as indicated by the first graph 202, but actually peaks between 0.6s and 0.8s, at 139 MW of power. This effect is amplified for the third graph 206, which includes measurements taken at a frequency of 10 Hz. Although the total generated energy is the same for the third graph 206 as the first 202 and second 204, the distribution of energy generated is not constant and is more variable than indicated in the second graph 204. In particular, a low of 87 MW is generated between 0.3s and 0.4s, whilst a high of 144 MW is generated between 0.7s and 0.8s.

This variability in energy generation underlines why it is important and useful to record real-time high frequency measurements for energy generation and consumption. According to various embodiments, both the energy generation measurements and the energy consumption measurements are recorded in real-time at high frequencies, and then matched to each other accordingly to create a plurality of linked groups of data. Each linked group of data corresponds to a specific measurement time or timestamp within a continuous stream of measurement times. By matching at this level of granularity, before aggregating energy generation and consumption statistics over a longer period of time (such as ten minutes, half an hour, an hour or a day), the precise and accurate nature of the high frequency measurements is conserved. The further processing performed on the matched data within the linked groups of data, to for example, calculate an energy excess or deficit, a carbon intensity per consumer, a carbon content per consumer, or a consumed energy mix per consumer, provides a measurement tool that allows optimisation of energy consumption at an individual consumer level. In particular, the system according to the embodiments described here provides highly accurate and precise data relating to the carbon emissions of each individual consumer, and each individual energy generator. From this data, actions may be performed by the energy generator, the system, or the energy consumer to monitor and manage the carbon intensity of the particular energy consumer's energy consumption.

It is to be understood that, whilst the above description regarding the processing of the linked group of data indicates that processing is done on each linked group of data, such processing is not required to be performed individually, and may be performed once per extended period of time of a set of linked groups of data. Although the period of time is 5s in Table 1, the extended period of time could be any length of time, for example, 30 seconds, a minute, an hour, a day, a week, a month or a year. Thus, computation of the excess, deficit, carbon content and carbon intensity values may occur periodically. Since, in each of these instances, data is still measured in real-time and used to form linked groups of data, the benefits set out above are conserved over the period of time. Since the data is stored in linked groups, the matching of data is conserved, and linked groups of data may be processed a plurality at a time. For example, the real-time carbon content may be calculated periodically for set of linked groups of data based on the deficits for each of the groups. Similarly, the carbon intensity score may be calculated periodically and/or after the extended period of time based on the accumulation of real-time carbon content. Thus, processing can for each linked group of data iteratively or per set of linked groups of data periodically. Since each linked group of data preserves the matching of the data at a specific moment in time indicated by the temporal metadata, the end result from performing either of these types of processing is unchanged.

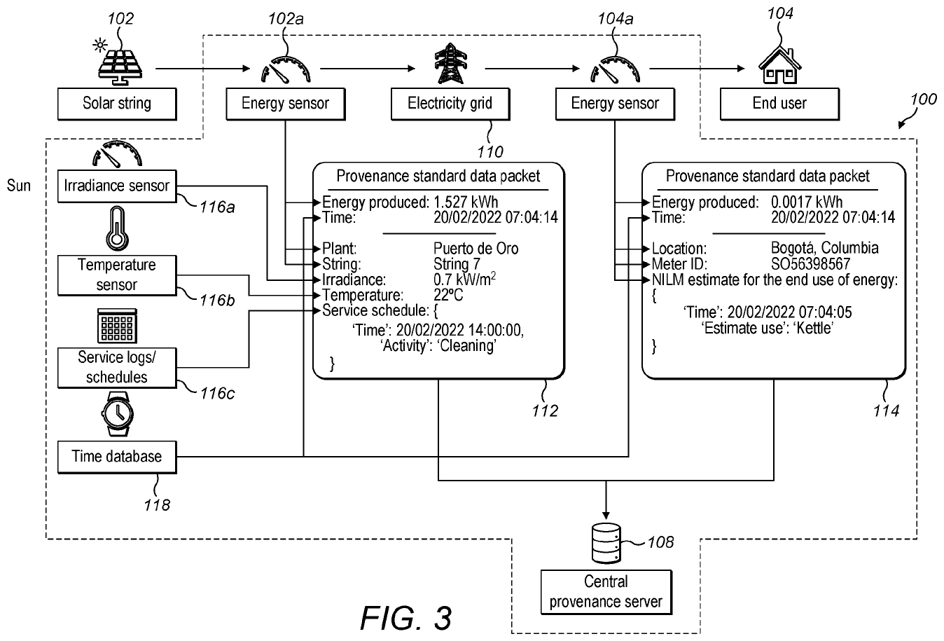

FIG. 3 shows a schematic diagram of an example of the energy tracking system 100. The energy tracking system 100 operates within an electrical grid 110 and is connected at an energy generator end to an energy generator 102, and at an energy consumer end to an energy consumer 104. The energy tracking system 100 includes an energy generator sensor 102a, an energy consumption sensor 104a, and a computing device 108. FIG. 3 also shows an example of an energy generator data packet 112 and an energy consumption data packet 114, formed at least in part by the energy generator sensor 102a and the energy consumption sensor 104a respectively.

As exemplified in FIG. 3, the energy generator data packet 112 includes real-time energy generator measurement data from the energy generator sensor 102a indicating the amount of energy generated by the energy generator 102. The energy generator data packet 112 further includes associated metadata including a measurement time, indicating the time at which the measurement or reading was performed by the energy generator sensor 102a. The measurement time may be considered temporal metadata. The measurement time is measured according to a global clock signal received from a global clock 118. The global clock may be provided by any suitable system that includes a clock, such as the Global Positioning System (GPS). The energy generator data packet 112 further includes additional metadata including an indication of the energy generator for which the measurement was taken (Puerto de Oro); an activity associated with the energy generator at the time at which the measurement was taken (cleaning); and further ancillary sensor data. The further ancillary sensor data is provided by ancillary sensors 116a to 116c. The first ancillary sensor 116a is an irradiance sensor, the second ancillary sensor 116b is a temperature sensor, and the third ancillary sensor 116c is a service log/schedule associated with the energy generator 102. The ancillary sensor data provides information regarding the energy generator 102.

The energy consumption data packet 114 further includes metadata including a measurement time, indicating the time at which the measurement or reading was performed by the energy consumption sensor 104a. The measurement time may be considered temporal metadata. The measurement time is measured according to a global clock signal received from a global clock 118. The energy consumption data packet 114 further includes additional metadata including an indication of the location of the energy consumer 104 (Bogota); an activity associated with the consumer 104 at which the measurement was taken (kettle); and identification of a consumer or meter associated with the energy consumer 104.

The energy generator data packet 112 and the energy consumption data packet 114 are sent to the computing device 108. In FIG. 3, the computing device 108 is exemplified as a central server.

Although only one energy generator 102 is illustrated in FIG. 3, it is to be understood that there may be a plurality of different energy generators 102 being monitored by multiple energy generator sensors 102a. These sensors may be of different types, configured to measure different aspects or components of the energy generator 102.

In FIG. 3, the energy generator 102 is a solar energy generator comprising a solar string. The solar energy generator is a photovoltaic plant that includes several components used to form a system necessary for converting solar energy into electrical energy appropriate for transmission through the electrical grid. Such systems include supporting equipment, which serves to balance the system and to make it sustainably operational. Components of the system include, for example, inverters, controllers, transformers, wiring, connector boxes, switches, monitoring devices, charge regulators, and energy storage devices. This supporting infrastructure is referred to as ‘balance of system’ (BOS). Individual Photovoltaic Modules (PVM) are usually connected in a string in photovoltaic plants. Multiple strings are connected to a combiner box, which is in turn connected to an inverter and a transformer for providing energy to the electrical grid. Additional strings can be added to the system, such that the system is effectively modular.

The system 100 may include more than one energy generator sensor 102a for each energy generator 102. For the solar energy generator 102 of FIG. 3, the system 100 may include energy generator sensors 102a at one or more of these components. For example, each of the multiple sensors may be associated with a PVM, a string, the combiner box, the inverter and/or the transformer, for example. Using multiple sensors 102a per energy generator 102 allows for sensor redundancy, such that energy generated can still be measured should one or more but not all of the sensors fail. Furthermore, using multiple sensors provides a more reliable energy measurement, since measurements from each of the sensors can be combined/averaged and/or compared to identify erroneous readings. The multiple sensors may include temperature, power factor, impendence, current and voltage sensors, for example. Finally, using multiple sensors at different components in the energy generator can be beneficial in fault identification procedures, since irregular measurement readings from a particular sensor associated with a particular component may indicate that a fault exists with said particular component. For example, using an imaging sensor to provide thermographic imaging to detect and classify heating patterns across PV panels can aid in indicating the presence of a fault in a PV plant.

Furthermore, the ancillary sensors 116a to 116c and the resultant ancillary sensor data included in the energy generator data packets 112 may be used to verify the performance of the energy generator 102 and/or the energy generator sensor 102. For example, in FIG. 3, ancillary sensor data indicating the irradiance and temperature at the photovoltaic plant energy generator 102 may be used to calculate predicted energy generation levels for the energy generator 102. Generally, higher temperatures equate to a lower output whilst higher irradiance indicates a higher energy output. If such levels are not met by the energy generator 102 or detected by the energy generator sensor 102a, it is determined that a fault exists at either of these components. The computing device 108 may perform this analysis and output a notification or error message when it is determined that a fault may exist.

Similarly, multiple sensors 104a may be provided at each energy consumer 104, and/or at individual components at the energy consumer 104, to improve reliability, provide sensor redundancy, and for use in fault identification.

As shown in FIG. 3, the energy generator data packet 112 and the energy consumption data packet 114 indicate an identical time of energy generation and energy consumption (07:04:14). As such, these data packets will be matched by the computing device 108. Since the energy generated and consumed is measured in real-time and at high frequency by the energy generation sensor 102a and the energy consumption sensor 104a, many different energy measurements are made and recorded against a time measurement by the sensors in a continuous manner. In order to ensure that the correct energy generation measurement is matched by the computing device 108 to a corresponding energy consumption measurement at the same time, the global clock 118 is maintained separately to the energy generator sensor 102a and the energy consumption sensor 104a. The global clock signal from the global clock 118 feeds the energy generator signal 102a and the energy consumption sensor 104a with a common and identical timing reference such that real-time measurements taken at the same time are recorded as such in temporal metadata. The global clock 118 may also provide the global clock signal to each of the ancillary sensors 116a to 116c for the same purpose. This ensures that the energy generator data packet 112 includes metadata collected at the exact same time as the collected energy generation measurement data. Alternatively, clock signals at each of the energy generator sensor 102a and the energy consumption sensor 104a may be synchronised using the Network Time Protocol (NTP) or the like.

As explained above, data packets that are linked or matched to each other on the basis of the temporal metadata (e.g. a time-stamp) are stored or reference to the link is stored in a relational database at the computing device 108.

As shown in FIG. 3, the energy generator data packet 112 and the energy consumption data packet 114 are in a preconfigured format. The preconfigured format is used to ensure that the computing device 108 can interact with every data packet, and that each of the sensors 102a and 104a are able to provide data that is understandable by the computing device 108. Furthermore, using the same preconfigured format for sending, analysing and processing data throughout the system 100 allows for export or access of the data to a user such as an energy generator operator or consumer 104 in a simple and effective manner.

The energy generator sensors 102a and the energy consumption sensors 104a may not provide the energy generator and energy consumption measurements in the preconfigured format. In this case, the energy generator measurements and the energy consumption measurements are translated into the preconfigured format at the computing device 108. In particular, the preconfigured format is associated with a predetermined vocabulary of terms and/or headers that describe features of the system, such as an energy generator, an energy consumer, names, identifications and locations thereof, and names and headings of other metadata. The predetermined vocabulary may be shared with energy generators 102 and/or energy consumers 104 so that they can access and understand the data defined by the data packets in the preconfigured format. It is to be understood that the predetermined vocabulary is determined based on the particular application and setting in which the system is used, and is thus dependent on the type of energy generators in the system and the components/sensors used to provide data.

The computing device 108 is configured to be capable of receiving pre-formed data packets in the preconfigured format, and/or creating the energy generator data packets 112 and the energy consumption data packets 114 based on received measurements and metadata, including temporal metadata. When incoming data is not in the preconfigured format, the computing device 108 is configured to retrieve, from the sensors 102a and 104a, energy generator measurements and energy consumption measurements and store them on a time-series database against temporal metadata (e.g. timestamps) obtained from the synchronised clock. Any additional metadata explaining the source of the measurement data, such as, and not limited to: sensor features, clock synchronisation method, location of sensor, equipment connected to sensor, etc. are added to the measurement data and the temporal data to form the data packets. These data packets in the time-series database are then matched as explained above, to form linked groups of data that are stored on the separate relational database of the computing device 108.

As illustrated in FIG. 3, the preconfigured format may be based on the Provenance data model (PROV-DM). Provenance is information about entities, activities, and people involved in producing a piece of data or thing, which can be used to form assessments about its quality, reliability or trustworthiness. PROV-DM is the conceptual data model that forms a basis for the W3C provenance (PROV) family of specifications. PROV-DM is organized in six components, respectively dealing with: (1) entities and activities, and the time at which they were created, used, or ended; (2) derivations of entities from entities; (3) agents bearing responsibility for entities that were generated and activities that happened; (4) a notion of bundle, a mechanism to support provenance of provenance; (5) properties to link entities that refer to the same thing; and, (6) collections forming a logical structure for its members. At its core, provenance describes the use and production of entities by activities, which may be influenced in various ways by agents. In general terms, an entity is a physical, digital, conceptual, or other kind of thing with some fixed aspects. In the system 100, the energy in the system 100 is the entity. The energy is indicated by the energy generation and consumption measurements. These may be represented by further entities such as datasets comprising current, voltage, power, power factor, reactive and real power, and/or the like, which are processed by an activity to generated the generated energy or consumed energy entities. An activity is something that occurs and acts upon or with entities; it may include consuming, processing, transforming, modifying, relocating, using, or generating entities. In the system 100, the activity may be generating or consuming energy, as well as the processing, such as accumulating/summing generated energy, calculating the carbon content and calculating the carbon intensity. An agent is something that bears some form of responsibility for an activity taking place, for the existence of an entity, or for another agent's activity. An agent may be a particular type of entity or activity. In the system 100, the energy consumer 104 and the energy generator 102 are agents. There may also be different agents. Such agents may further include any party involved in using, managing, monitoring, and/or supplying assets that form part of the energy system, for example including the consumers of electricity, the provider of engineering services, or the sensor system operator.

In the system 100, PROV-DM is used to form the energy generator data packets 112 and the energy consumption data packets 114. In particular, the data packets include identification of activities relating to the generation and consumption of energy, the time at which energy is generated and consumed, and properties such as metadata and temporal metadata that link entities together. The computing device 108 is configured to generate the PROV data packets, including the sensor data, asset data, and additional metadata, etc. The PROV data packets are stored in a PROV-STORE. The PROV-STORE may hold pointers to specific data points held in separate tables (in the time-series database or other) rather than exact data-points. The computing device 108 is configured to match the energy generator data packets 112 and the energy consumption packets 114 based at least on their temporal metadata, to create the linked groups of data. The linked groups of data and any of the processing performed thereon as explained above are used by the computing device 108 to generate the relational database of organised data. The database may be implemented as a PROV trace, a type of directed acyclic graph that indicates the links between entities, activities and agents.

The vocabulary used to describe the system may be referred to as a PROV-vocabulary. The PROV vocabulary describes consumers, energy generator operators, sensors, energy matched or differences in energy consumed/produced (deficit/excess), calculators of carbon intensities, carbon content etc. The vocabulary is not fixed. It is extended to encompass all the entities, activities, and agents encountered in different energy production/consumption scenarios. The PROV vocabulary can be used by a third-party to augment their dataset with PROV. For example, an electric vehicle charging point operator can use the vocabulary to describe the agents (sensor, charger, vehicle, user), the activities (charging, discharging), and the entities (energy, connection status) that it is monitoring. Given the PROV data produced, this can be stored by the computing device 108 in the PROV-STORE to further connect the associated entities/agents/activities to those already held in the PROV-STORE. Thus, it is possible to provide access to third parties to augment the PROV-STORE with 3^{rd} party data in the preconfigured format.

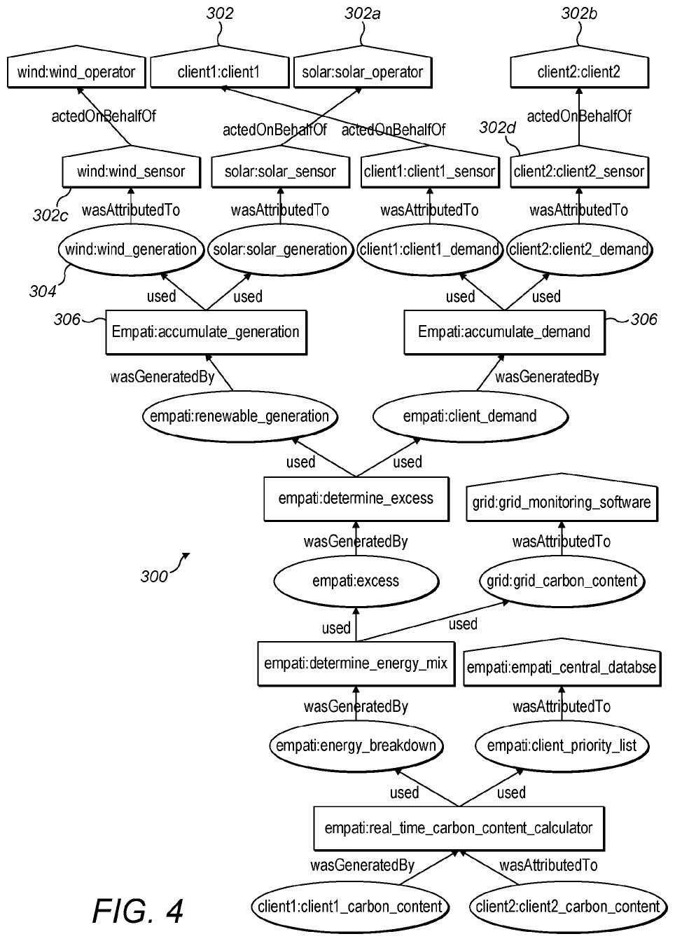

FIG. 4 shows a schematic diagram of an example PROV trace 300 that may be produced by the computing device 108. As noted above, the PROV trace is a directed acyclic graph including linked information. The PROV trace 300 includes agents 302, entities 304 and activities 306. The agents 302 include energy generators 302a, energy consumers 302b, energy generator sensors 302c and energy consumption sensors 302d. The entities include data relating to measurements, such as those from the sensors, as well as calculations and processing performed by the computing device 108, for example. Entities may thus include the sum of energy generated from the accumulation of energy generation measurements, the sum of energy consumed from the accumulation of energy consumption measurements, the energy excess or energy deficit, the total real-time carbon content, the carbon intensity score, and the real-time carbon content per individual consumer. Activities include the generation and consumption of energy, as well as the processing of data by the computing device, such as the summing of the energy generator measurements, the summing of energy consumption measurements, the determining of the energy excess or deficit, and the determining of the energy mix, the real-time carbon content, the carbon intensity score, and the real-time carbon content/carbon intensity per individual energy consumer.

FIG. 4 shows how these agents 302, entities 304, and activities 306 may be stored and linked by the computing device 108 using PROV to effectively provide an audit trail of the data obtained by the computing device and the processing performed thereon in order to reach one or more results, such as the real-time carbon content and the carbon intensity score.

By storing data in this way, the computing device 108 is able to provide a transparent history or audit trail of the data in the system 100, and how it has been manipulated, which can be exported or made available to a consumer or third party via access controls.

In some embodiments, the PROV trace may be stored using a distributed ledger, or blockchain secured by a cryptographic hash function. In this manner, the integrity of the PROV trace is secured. Multiple copies of the PROV trace are held across a distributed ledger which allows for a third-party to verify it was generated and stored at the time its owner claims it to have been generated and stored. The PROV trace would be uploaded by the owner of the PROV data to the distributed ledger at a time deemed appropriate (e.g., daily, hourly, every minute) and will include details of the links to the databases underlying the PROV data (i.e., sensor data, relational data etc.). The detailed implementation (read/write) of such distributed ledger is dependent on the particular distributed ledger technology used, as will be understood. The datasets, including data recorded by sensors and stored on the time-series database, are not stored on the blockchain themselves. They are recorded ‘Off-chain’. PROV data may include pointers to such off-chain datasets as explained above. The parties who need access to the PROV-TRACE or to the datasets will be provided with a key that gives them read/write permission to the blockchain (for example, to add their signature to a document) or to view the datasets and run their own calculations on it. The sharing and use of such keys will follow typical public/private key sharing or other similarly secure key sharing methods, as will be understood.

The PROV trace or stored database that includes the energy consumption and generation measurement data, as well as the determinations of excess/deficit, real-time carbon content, the carbon intensity score and the energy mix, may be made available by the computing device 108 to one or more energy consumers 104 and/or one or more energy generators 102 via a report or file that may be sent from the computing device 108. As indicated above, such information may also be provided via a display or over a communications network such as the internet. In particular, the computing device 108 is configured to communicate in a network with the energy generators 102 and the energy consumers 104. Energy generator operators or consumers may access or request access to the database stored by the computing device 108 as desired. In response to such requests, the computing device 108 may provide, via the network, the data from the stored database corresponding to said particular energy generator or consumer. The data may take the form of a report, such as a certificate of PROV. The data may take the form of the PROV trace. The data may be made available via a virtual interface on a web-page, for example.

Whilst the preconfigured format is described above using PROV, it is to be understood that other data models and protocols may be used for providing the preconfigured format, for creating a shared vocabulary and a means of tracking and auditing energy generation and consumption, and manipulations (e.g. calculations) using such data.

FIG. 5 shows an example of a virtual interface 400 provided to a consumer 104 for the purposes of providing information from the stored database of the computing device 108. The interface 400 includes determined data 402, calculated from the processing of the one or more linked groups of data as explained above, visual data 404, 406 and 408 indicative of the energy mix provided by one or more energy generators 102, and a visual representation 410 of additional metadata sourced from the energy generator data packets and/or the energy consumption data packets. The determined data 402 in FIG. 5 includes a percentage indicative of the energy consumed that originated from carbon-based sources as a proportion of the overall energy consumed. In FIG. 5, 3.34% of energy came from non-green energy generators. FIG. 5 thus shows a representation of one way of providing a consumer 104 with the data obtained and processed by the computing device 108 and stored in the database. In FIG. 5, location metadata from a plurality of energy generators and location metadata from the energy consumer is used to provide the visual representation 410. FIG. 5 also indicates the period of time 412 for which the data provided to the consumer 104 corresponds to. The embodiments described herein can thus be used to provide real-time carbon reporting to energy consumers.

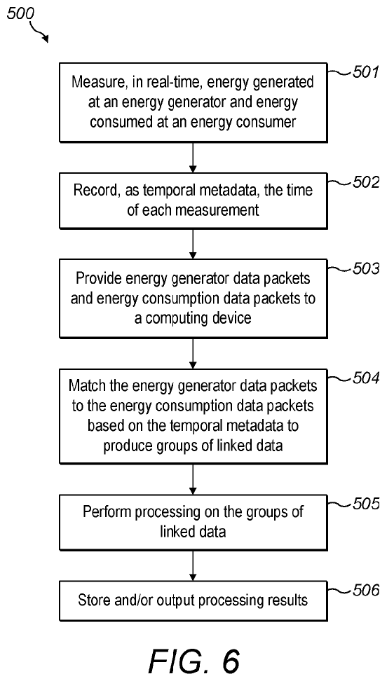

FIG. 6 shows a flow diagram 500 of the method performed by the system 100. In a first step 501, the method includes measuring, in real-time, energy generated at an energy generator and energy consumed at an energy consumer.

At a second step 502, the method includes recording, as temporal metadata, the time of each energy generation and energy consumption measurement. This second step is performed with the first step 501, such that each measurement is recorded with a corresponding time-of-measurement value.

At a third step 503, the method includes providing energy generator data packets and energy consumption data packets to a computing device. As noted previously, the energy generator packets include the energy generator measurement, the associated time of measurement, and any other generator metadata. The energy consumption packets include the energy consumption measurement, the associated time of measurement, and any other consumer metadata. It is to be understood that the energy generator packets and energy consumption packets may be generated at the computing device. In this case, the computing device receives sensor data including the temporal metadata together with the energy generation measurement and/or the energy consumption measurement. The computing device is then configured to generate the data packets from this sensor data.

At a fourth step 504, the method includes matching the energy generator data packets to the energy consumption data packets based on the temporal metadata to produce linked groups of data. The linked groups of data may be referred to as sets of matched measurements. Each linked group shares the same temporal metadata.

At a fifth step 505, processing is performed on the linked groups of data. The processing may include determining an energy mix, a real-time carbon content, a carbon intensity and/or an energy excess or deficit for each or several linked groups of data. Where the energy generators being monitored are renewable energy generators, the carbon content and carbon intensity is calculated based on the deficit compensated by energy from the grid. These parameters are calculated as explained above with reference to FIG. 1.

At a sixth step, 506, the method includes storing and/or outputting the results of the processing. The results may then be communicated to an operator of an energy generator or to a consumer, and may be used to provide reporting information, or to invoke further processing or responsive actions.

It is to be understood that the method 500 may include any additional features and steps as set out above and with respect to FIGS. 1 to 5.

The method described herein may be performed by software in machine readable form on a tangible storage medium e.g. in the form of a computer program comprising computer program code means adapted to perform all the steps of any of the methods described herein when the program is run on a computer and where the computer program may be embodied on a computer readable medium. Examples of tangible (or non-transitory) storage media include disks, thumb drives, memory cards etc. and do not include propagated signals. The software can be suitable for execution on a parallel processor or a serial processor such that the method steps may be carried out in any suitable order, or simultaneously.

This application acknowledges that firmware and software can be valuable, separately tradable commodities. It is intended to encompass software, which runs on or controls “dumb” or standard hardware, to carry out the desired functions. It is also intended to encompass software which “describes” or defines the configuration of hardware, such as HDL (hardware description language) software, as is issued for designing silicon chips, or for configuring universal programmable chips, to carry out desired functions.

The features and embodiments discussed above may be combined as appropriate, as would be apparent to a person skilled in the art, and may be combined with any of the aspects of the invention except where it is expressly provided that such a combination is not possible or the person skilled in the art would understand that such a combination is self-evidently not possible.

In the embodiments described above, a system 100 including a computing device 108 is described. The computing device 108 may be a server. The server may comprise a single server or network of servers. In some examples, the functionality of the server may be provided by a network of servers distributed across a geographical area, such as a worldwide distributed network of servers, and a user (consumer or operator) may be connected to an appropriate one of the network servers based upon, for example, a user location.

The above description discusses embodiments of the invention with reference to a single user for clarity. It will be understood that in practice the system may be shared by a plurality of users, and possibly by a very large number of users simultaneously.

The embodiments described above are fully automatic. In some examples a user or operator of the system may manually instruct some steps of the method to be carried out.

In the described embodiments, the computing device 108 and other similar devices may be implemented as any form of a computing and/or electronic device. Such a device may comprise one or more processors which may be microprocessors, controllers or any other suitable type of processors for processing computer executable instructions to control the operation of the device in order to gather and record routing information. In some examples, for example where a system on a chip architecture is used, the processors may include one or more fixed function blocks (also referred to as accelerators) which implement a part of the method in hardware (rather than software or firmware). Platform software comprising an operating system or any other suitable platform software may be provided at the computing-based device to enable application software to be executed on the device.

Various functions described herein can be implemented in hardware, software, or any combination thereof. If implemented in software, the functions can be stored on or transmitted over as one or more instructions or code on a computer-readable medium. Computer-readable media may include, for example, computer-readable storage media. Computer-readable storage media may include volatile or non-volatile, removable or non-removable media implemented in any method or technology for storage of information such as computer readable instructions, data structures, program modules or other data. A computer-readable storage media can be any available storage media that may be accessed by a computer. By way of example, and not limitation, such computer-readable storage media may comprise RAM, ROM, EEPROM, flash memory or other memory devices, CD-ROM or other optical disc storage, magnetic disc storage or other magnetic storage devices, or any other medium that can be used to carry or store desired program code in the form of instructions or data structures and that can be accessed by a computer. Disc and disk, as used herein, include compact disc (CD), laser disc, optical disc, digital versatile disc (DVD), floppy disk, and Blu-ray (RTM) disc (BD). Further, a propagated signal is not included within the scope of computer-readable storage media. Computer-readable media also includes communication media including any medium that facilitates transfer of a computer program from one place to another. A connection, for instance, can be a communication medium. For example, if the software is transmitted from a website, server, or other remote source using a coaxial cable, fibre optic cable, twisted pair, DSL, or wireless technologies such as infrared, radio, and microwave are included in the definition of communication medium. Combinations of the above should also be included within the scope of computer-readable media.

Alternatively, or in addition, the functionality described herein can be performed, at least in part, by one or more hardware logic components. For example, and without limitation, hardware logic components that can be used may include Field-programmable Gate Arrays (FPGAs), Program-specific Integrated Circuits (ASICs), Program-specific Standard Products (ASSPs), System-on-a-chip systems (SOCs). Complex Programmable Logic Devices (CPLDs), etc.

Although illustrated as a single system, it is to be understood that the computing device may be a distributed system. Thus, for instance, several devices may be in communication by way of a network connection and may collectively perform tasks described as being performed by the computing device.

Although illustrated as a local device it will be appreciated that the computing device may be located remotely and accessed via a network or other communication link (for example using a communication interface).

The term ‘computer’ and ‘computing device’ is used herein to refer to any device with processing capability such that it can execute instructions. Those skilled in the art will realise that such processing capabilities are incorporated into many different devices and therefore the term ‘computer’ includes PCs, servers, mobile telephones, personal digital assistants and many other devices.

Those skilled in the art will realise that storage devices utilised to store program instructions can be distributed across a network. For example, a remote computer may store an example of the process described as software. A local or terminal computer may access the remote computer and download a part or all of the software to run the program. Alternatively, the local computer may download pieces of the software as needed, or execute some software instructions at the local terminal and some at the remote computer (or computer network). Those skilled in the art will also realise that by utilising conventional techniques known to those skilled in the art that all, or a portion of the software instructions may be carried out by a dedicated circuit, such as a DSP, programmable logic array, or the like.

Any reference to ‘an’ item refers to one or more of those items. The term ‘comprising’ is used herein to mean including the method steps or elements identified, but that such steps or elements do not comprise an exclusive list and a method or apparatus may contain additional steps or elements.

As used herein, the terms “component” and “system” are intended to encompass computer-readable data storage that is configured with computer-executable instructions that cause certain functionality to be performed when executed by a processor. The computer-executable instructions may include a routine, a function, or the like. It is also to be understood that a component or system may be localized on a single device or distributed across several devices.

Further, as used herein, the term “exemplary” is intended to mean “serving as an illustration or example of something”. Further, to the extent that the term “includes” is used in either the detailed description or the claims, such term is intended to be inclusive in a manner similar to the term “comprising” as “comprising” is interpreted when employed as a transitional word in a claim.

Moreover, the acts described herein may comprise computer-executable instructions that can be implemented by one or more processors and/or stored on a computer-readable medium or media. The computer-executable instructions can include routines, sub-routines, programs, threads of execution, and/or the like. Still further, results of acts of the methods can be stored in a computer-readable medium, displayed on a display device, and/or the like.

The order of the steps of the methods described herein is exemplary, but the steps may be carried out in any suitable order, or simultaneously where appropriate. Additionally, steps may be added or substituted in, or individual steps may be deleted from any of the methods without departing from the scope of the subject matter described herein. Aspects of any of the examples described above may be combined with aspects of any of the other examples described to form further examples without losing the effect sought.

It will be understood that the above description of a preferred embodiment is given by way of example only and that various modifications may be made by those skilled in the art. What has been described above includes examples of one or more embodiments. It is, of course, not possible to describe every conceivable modification and alteration of the above devices or methods for purposes of describing the aforementioned aspects, but one of ordinary skill in the art can recognize that many further modifications and permutations of various aspects are possible.

1. A computer-implemented method of real-time energy-tracking, the method comprising:
measuring, in real-time with an energy generation sensor, energy generated at an energy generator to obtain a plurality of generated energy measurements over a period of time;
measuring, in real-time with an energy consumption sensor, energy consumed by an energy consumer to obtain a plurality of consumed energy measurements over the period of time;
receiving a plurality of generator data packets, each generator data packet including one of the plurality of generated energy measurements, and associated generator metadata including temporal data corresponding to a time at which the one of the plurality of generated energy measurements was measured;
receiving a plurality of consumption data packets, each consumption data packet including one of the plurality of consumed energy measurements, and associated consumer metadata including temporal data corresponding to a time at which the one of the plurality of consumed energy measurements was measured;
matching the plurality of generated energy measurements to the plurality of consumed energy measurements according to the temporal data from each of the generator metadata and the consumer metadata to obtain a plurality of sets of matched measurements over the period of time; and
for each of the sets of matched measurements over the period of time, determining and outputting a real-time energy deficit or excess by comparing the generated energy measurement to its matched consumed energy measurement.

2-26. (canceled)
